(19) United States
(12) Patent Application Publication
(10) Pub. No.: US 2020/0203592 A1
(43) Pub. Date: Jun. 25, 2020

(54) ELECTRIC POWER GENERATION FROM A THIN-FILM BASED THERMOELECTRIC MODULE PLACED BETWEEN EACH HOT PLATE AND COLD PLATE OF A NUMBER OF HOT PLATES AND COLD PLATES

(71) Applicants: Sridhar Kasichainula, Fremont, CA (US); William H. Davidson, Rancho Mirage, CA (US)

(72) Inventors: Sridhar Kasichainula, Fremont, CA (US); William H. Davidson, Rancho Mirage, CA (US)

(21) Appl. No.: 16/804,014

(22) Filed: Feb. 28, 2020

Related U.S. Application Data
(63) Continuation-in-part of application No. 16/207,076, filed on Nov. 30, 2018.
Application No. 16/207,076 is a continuation-in-part of application No. 16/779,668, filed on Feb. 3, 2020.
Application No. 16/207,076 is a continuation-in-part of application No. 15/808,902, filed on Nov. 10, 2017.
Application No. 16/779,668 is a continuation-in-part of application No. 15/808,902, filed on Nov. 10, 2017.
Application No. 15/808,902 is a continuation-in-part of application No. 14/564,072, filed on Dec. 8, 2014, now abandoned.
Application No. 15/808,902 is a continuation-in-part of application No. 14/711,810, filed on May 14, 2015, now Pat. No. 10,141,492.
Application No. 14/711,810 is a continuation-in-part of application No. 15/368,683, filed on Dec. 5, 2016, now Pat. No. 10,290,794.
(60) Provisional application No. 61/912,561, filed on Dec. 6, 2013.

(51) Int. Cl. H01L 35/34; H01L 35/32; H01L 35/04; H01L 21/02

(52) U.S. Cl. CPC H01L 35/34; H01L 21/02631; H01L 35/04; H01L 35/32

(57) ABSTRACT

A method includes sputter depositing pairs of N-type thermoelectric legs and P-type thermoelectric legs electrically in contact with one another on each of a number of flexible substrates to form a number of thin-film based thermoelectric modules. The method also include placing a first surface and a second surface of the each of the formed number of thin-film based thermoelectric modules in surface contact with a hot plate and a cold plate respectively to form an electric power generation device, and deriving electric power from the electric power generation device based on maintaining a temperature difference between the first surface and the second surface of the each of the formed number of thin-film based thermoelectric modules based on the surface contact thereof with the hot plate and the cold plate respectively.

### CLAIM OF PRIORITY

This application is a Continuation-in-Part application of co-pending U.S. patent application Ser. No. 16/207,076 titled DOUBLE-SIDED METAL CLAD LAMINATE BASED FLEXIBLE THERMOELECTRIC DEVICE AND MODULE filed on Nov. 30, 2018 and co-pending U.S. patent application Ser. No. 16/779,668 titled SERIES-PARALLEL CLUSTER CONFIGURATION OF A THIN-FILM BASED THERMOELECTRIC MODULE filed on Feb. 3, 2020, both of which are Continuation-in-Part applications of co-pending U.S. patent application Ser. No. 15/808,902 titled FLEXIBLE THIN-FILM BASED THERMOELECTRIC DEVICE WITH SPUTTER DEPOSITED LAYER OF N-TYPE AND P-TYPE THERMOELECTRIC LEGS filed on Nov. 10, 2017, which is a Continuation-in-Part application of U.S. patent application Ser. No. 14/564,072 titled VOLTAGE GENERATION ACROSS TEMPERATURE DIFFERENTIALS THROUGH A THERMOELECTRIC LAYER COMPOSITE filed on Dec. 8, 2014, which is a conversion application of U.S. Provisional Application No. 61/912,561 also titled VOLTAGE GENERATION ACROSS TEMPERATURE DIFFERENTIALS THROUGH A THERMOELECTRIC LAYER COMPOSITE filed on Dec. 6, 2013, U.S. patent application Ser. No. 14/711,810 titled ENERGY HARVESTING FOR WEARABLE TECHNOLOGY THROUGH A THIN FLEXIBLE THERMOELECTRIC DEVICE filed on May 14, 2015 and issued as U.S. Pat. No. 10,141,492 on Nov. 27, 2018, and U.S. patent application Ser. No. 15/368,683 titled PIN COUPLING BASED THERMOELECTRIC DEVICE filed on Dec. 5, 2016 and issued as U.S. Pat. No. 10,290,794 on May 14, 2019. The contents of all of the aforementioned applications are incorporated by reference in entirety thereof.

### FIELD OF TECHNOLOGY

This disclosure relates generally to thermoelectric devices and, more particularly, to electric power generation from a thin-film based thermoelectric module placed between each hot plate and cold plate of a number of hot plates and cold plates.

### BACKGROUND

A thermoelectric device may be formed from alternating N and P elements/legs made of semiconducting material on a rigid substrate (e.g., alumina) joined on a top thereof to another rigid substrate/plate (e.g., again, alumina). Addition of more sets of N and P elements/legs in series in a bulk thermoelectric module formed out of the aforementioned alternating N and P elements/legs may lead to increased series resistance, thereby lowering an output current of the bulk thermoelectric module to non-functional levels. Further, a process of manufacturing the bulk thermoelectric module may not be scalable with respect to a number of thermoelectric legs. The aforementioned lack of scalability may severely limit use of the aforementioned bulk thermoelectric module in target applications involving electric power generation.

### SUMMARY

Disclosed are methods, a device and/or a system of electric power generation from a thin-film based thermoelectric module placed between each hot plate and cold plate of a number of hot plates and cold plates.

In one aspect, a method includes sputter depositing pairs of N-type thermoelectric legs and P-type thermoelectric legs electrically in contact with one another on each of a number of flexible substrates to form a number of thin-film based thermoelectric modules. The each of the number of flexible substrates is aluminum (Al) foil, a sheet of paper, polytetrafluoroethylene, polyimide, plastic, a single-sided copper (Cu) clad laminate sheet and/or a double-sided Cu clad laminate sheet, and the each of the number of flexible substrates has a dimensional thickness less than or equal to 25 μm. The method also includes rendering each of the formed number of thin-film based thermoelectric modules less than or equal to 100 μm in dimensional thickness.

A layer of the each of the formed number of thin-film based thermoelectric modules including the sputter deposited N-type thermoelectric legs and the P-type thermoelectric legs has a dimensional thickness less than or equal to 25 μm. Further, the method includes placing a first surface and a second surface of the each of the formed number of thin-film based thermoelectric modules in surface contact with a hot plate and a cold plate respectively. The hot plate and the cold plate are parallel to one another, and the hot plate is configured to be at a higher temperature than the cold plate, and the placing of the each of the formed number of thin-film based thermoelectric modules in surface contact with the hot plate and the cold plate forms an electric power generation device including a number of alternating hot plates and cold plates in between each of which is a thin-film based thermoelectric module of the formed number of thin-film based thermoelectric modules.

Still further, the method includes deriving electric power from the electric power generation device based on maintaining a temperature difference between the first surface and the second surface of the each of the formed number of thin-film based thermoelectric modules based on the surface contact thereof with the hot plate and the cold plate respectively.

In another aspect, a method includes sputter depositing pairs of N-type thermoelectric legs and P-type thermoelectric legs electrically in contact with one another on each of a number of flexible substrates to form a number of thin-film based thermoelectric modules. The each of the number of flexible substrates is Al foil, a sheet of paper, polytetrafluoroethylene, polyimide, plastic, a single-sided Cu clad laminate sheet and/or a double-sided Cu clad laminate sheet, and the each of the number of flexible substrates has a dimensional thickness less than or equal to 25 μm. The method also includes rendering each of the formed number of thin-film based thermoelectric modules less than or equal to 100 μm in dimensional thickness. A layer of the each of the formed number of thin-film based thermoelectric modules including the sputter deposited N-type thermoelectric legs and the P-type thermoelectric legs has a dimensional thickness less than or equal to 25 μm.

Further, the method includes placing a first surface and a second surface of the each of the formed number of thin-film based thermoelectric modules in surface contact with a hot plate and a cold plate respectively. The hot plate and the cold plate are parallel to one another, and the placing of the each of the formed number of thin-film based thermoelectric modules in surface contact with the hot plate and the cold plate forms an electric power generation device including a number of alternating hot plates and cold plates in between each of which is a thin-film based thermoelectric module of the formed number of thin-film based thermoelectric modules. Still further, the method includes providing a supply of a first fluid and a second fluid to the hot plate and the cold plate respectively to enable the hot plate to be at a higher temperature than the cold plate, and deriving electric power from the electric power generation device based on maintaining a temperature difference between the first surface and the second surface of the each of the formed number of thin-film based thermoelectric modules based on the surface contact thereof with the hot plate and the cold plate respectively.

In yet another aspect, a method includes sputter depositing pairs of N-type thermoelectric legs and P-type thermoelectric legs electrically in contact with one another on each of a number of flexible substrates to form a number of thin-film based thermoelectric modules. The each of the number of flexible substrates is Al foil, a sheet of paper, polytetrafluoroethylene, polyimide, plastic, a single-sided Cu clad laminate sheet and/or a double-sided Cu clad laminate sheet, and the each of the number of flexible substrates has a dimensional thickness less than or equal to 25 μm. The method also includes rendering each of the formed number of thin-film based thermoelectric modules less than or equal to 100 μm in dimensional thickness. A layer of the each of the formed number of thin-film based thermoelectric modules including the sputter deposited N-type thermoelectric legs and the P-type thermoelectric legs has a dimensional thickness less than or equal to 25 μm.

Further, the method includes placing a first surface and a second surface of the each of the formed number of thin-film based thermoelectric modules in surface contact with a hot plate and a cold plate respectively. The hot plate and the cold plate are parallel to one another, and the placing of the each of the formed number of thin-film based thermoelectric modules in surface contact with the hot plate and the cold plate forms an electric power generation device including a number of alternating hot plates and cold plates in between each of which is a thin-film based thermoelectric module of the formed number of thin-film based thermoelectric modules.

Still further, the method includes providing a supply of a first fluid and a second fluid to the hot plate and the cold plate respectively to enable the hot plate to be at a higher temperature than the cold plate, designing the hot plate and/or the cold plate for a laminar flow or a turbulent flow of the corresponding first fluid and/or the second fluid therethrough, and deriving electric power from the electric power generation device based on maintaining a temperature difference between the first surface and the second surface of the each of the formed number of thin-film based thermoelectric modules based on the surface contact thereof with the hot plate and the cold plate respectively.

Other features will be apparent from the accompanying drawings and from the detailed description that follows.

### BRIEF DESCRIPTION OF THE DRAWINGS

The embodiments of this invention are illustrated by way of example and not limitation in the figures of the accompanying drawings, in which like references indicate similar elements and in which:

FIG. 1 is a schematic view of a thermoelectric device.

FIG. 2 is a schematic view of an example thermoelectric device with alternating P and N elements.

FIG. 3 is a top schematic view of a thermoelectric device component, according to one or more embodiments.

FIG. 4 is a process flow diagram detailing the operations involved in realizing a patterned flexible substrate of a thermoelectric device as per a design pattern, according to one or more embodiments.

FIG. 5 is a schematic view of the patterned flexible substrate of FIG. 4, according to one or more embodiments.

FIG. 6 is a schematic view of the patterned flexible substrate of FIG. 4 with N-type thermoelectric legs, P-type thermoelectric legs, a barrier layer and conductive interconnects, according to one or more embodiments.

FIG. 7 is a process flow diagram detailing the operations involved in sputter deposition of the N-type thermoelectric legs of FIG. 6 on the patterned flexible substrate (or, a seed metal layer) of FIG. 5, according to one or more embodiments.

FIG. 8 is a process flow diagram detailing the operations involved in deposition of the barrier layer of FIG. 6 on top of the sputter deposited pairs of P-type thermoelectric legs and the N-type thermoelectric legs of FIG. 6 and forming the conductive interconnects of FIG. 6 on top of the barrier layer, according to one or more embodiments.

FIG. 9 is a process flow diagram detailing the operations involved in encapsulating the thermoelectric device of FIG. 4 and FIG. 6, according to one or more embodiments.

FIG. 10 is a schematic view of a flexible thermoelectric device embedded within a watch strap of a watch completely wrappable around a wrist of a human being, according to one or more embodiments.

FIG. 11 is a schematic view of a flexible thermoelectric device wrapped around a heat pipe, according to one or more embodiments.

FIG. 12 is a schematic view of example wiring configurations of an example set of four equivalent thermoelectric generators (TEGs) including a series configuration, a parallel configuration and a series-parallel configuration.

FIG. 13 is a schematic view of a two cluster series-parallel configuration of a thermoelectric device component analogous to the thermoelectric device component of FIG. 3, according to one or more embodiments.

FIG. 14 is a schematic view of a four cluster series-parallel configuration of a thermoelectric device component analogous to the thermoelectric device component of FIG. 3, according to one or more embodiments.

FIG. 15 is a schematic view of a six cluster series-parallel configuration of a thermoelectric device component analogous to the thermoelectric device component of FIG. 3, according to one or more embodiments.

FIG. 16 is a schematic front view of a thermoelectric device component in a double-sided substrate configuration, according to one or more embodiments.

FIG. 17 is a schematic view of an electric power generation device, according to one or more embodiments.

FIG. 18 is a schematic view of examples of channelization of a hot input/cold input into a corresponding hot plate/cold plate of the electric power generation device of FIG. 17.

FIG. 19 is a schematic view of an example set of tubes formed inside a thickness of a corresponding hot plate/cold plate of the electric power generation device of FIG. 17.

FIG. 20 is a schematic view of an example set of grooves formed within a thickness of a hot plate/cold plate of the electric power generation device of FIG. 17 on an inside wall thereof.

FIG. 21 is a schematic view of a relatively fixed temperature difference maintained across surfaces of a hot plate and a cold plate in contact with a thin-film based thermoelectric module of the electric power generation device of FIG. 17.

FIG. 22 is a process flow diagram detailing the operations involved in realizing the electric power generation device of FIG. 17, according to one or more embodiments.

Other features of the present embodiments will be apparent from the accompanying drawings and from the detailed description that follows.

### DETAILED DESCRIPTION

Example embodiments, as described below, may be used to provide methods, a system and/or a device of electric power generation from a thin-film based thermoelectric module placed between each hot plate and cold plate of a number of hot plates and cold plates. Although the present embodiments have been described with reference to specific example embodiments, it will be evident that various modifications and changes may be made to these embodiments without departing from the broader spirit and scope of the various embodiments.

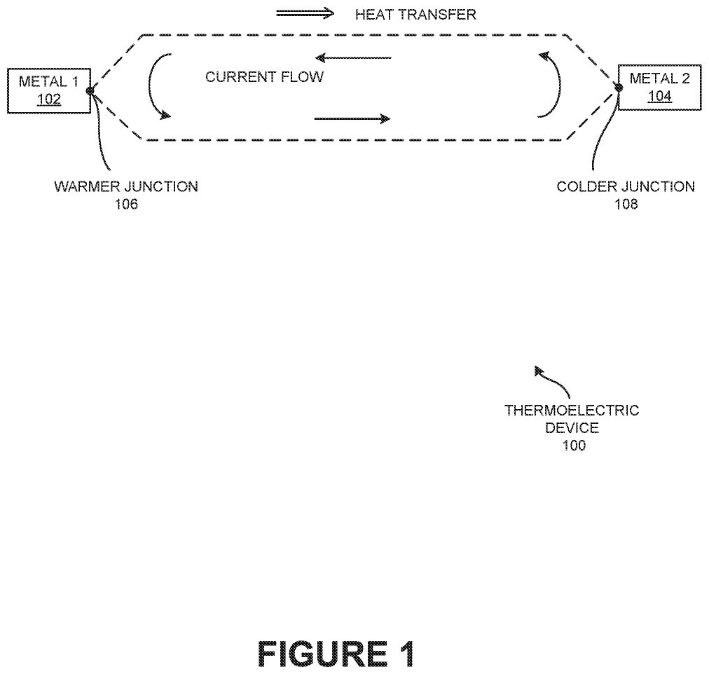

FIG. 1 shows a thermoelectric device 100. Thermoelectric device 100 may include different metals, metal 1 102 and metal 2 104, forming a closed circuit. Here, a temperature difference between junctions of said dissimilar metals leads to energy levels of electrons therein shifted in a dissimilar manner. This results in a potential/voltage difference between the warmer (e.g., warmer junction 106) of the junctions and the colder (e.g., colder junction 108) of the junctions. The aforementioned conversion of heat into electricity at junctions of dissimilar metals is known as Seebeck effect.

The most common thermoelectric devices in the market may utilize alternative P and N type legs/pellets/elements made of semiconducting materials. As heat is applied to one end of a thermoelectric device based on P and N type elements, charge carriers thereof may be released into the conduction band. Electron (charge carrier) flow in the N type element may contribute to a current flowing from the end (hot end) where the heat is applied to the other end (cold end). Hole (charge carrier) flow in the P type element may contribute to a current flowing from the other end (cold end) to the end (hot end) where the heat is applied. Here, heat may be removed from the cold end to prevent equalization of charge carrier distribution in the semiconductor materials due to migration thereof.

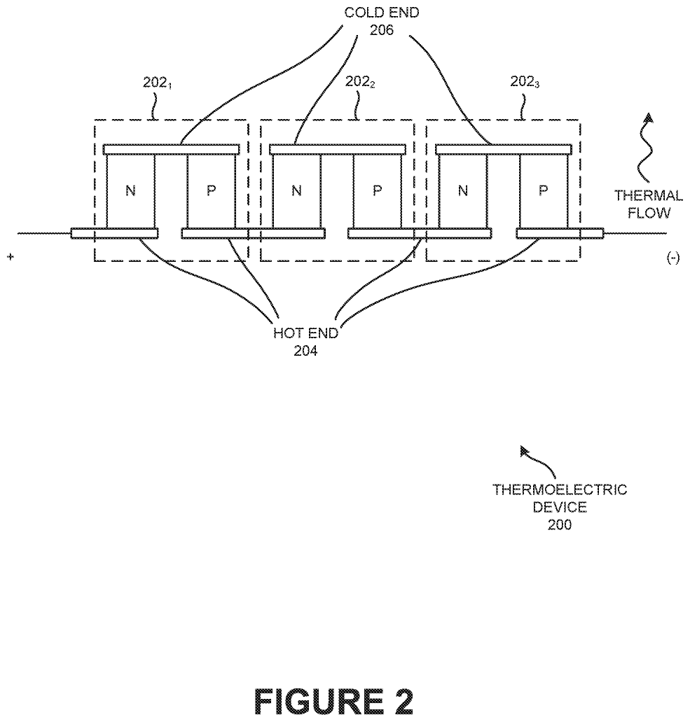

In order to generate voltage at a meaningful level to facilitate one or more application(s), typical thermoelectric devices may utilize alternating P and N type elements (legs/pellets) electrically coupled in series (and thermally coupled in parallel) with one another, as shown in FIG. 2. FIG. 2 shows an example thermoelectric device 200 including three alternating P and N type elements 202₁₋₃. The hot end (e.g., hot end 204) where heat is applied and the cold end (e.g., cold end 206) are also shown in FIG. 2.

Typical thermoelectric devices (e.g., thermoelectric device 200) may be limited in application thereof because of rigidity, bulkiness and high costs (> $20/watt) associated therewith. Also, these devices may operate at high temperatures using active cooling. Exemplary embodiments discussed herein provide for a thermoelectric platform (e.g., enabled via roll-to-roll sputtering on a flexible substrate (e.g., plastic)) that offers a large scale, commercially viable, high performance, easy integration and inexpensive (<20 cents/watt) route to flexible thermoelectrics.

In accordance with the exemplary embodiments, P and N thermoelectric legs may be deposited on a flexible substrate (e.g., plastic) using a roll-to-roll process that offers scalability and cost savings associated with the N and P materials. In a typical solution, bulk legs may have a height in millimeters (mm) and an area in mm². In contrast, N and P bulk legs described in the exemplary embodiments discussed herein may have a height in microns (μm) and an area in the μm² to mm² range.

Examples of flexible substrates may include but are not limited to aluminum (Al) foil, a sheet of paper, polytetrafluoroethylene (e.g., Teflon), plastic, polyimide and a single/double-sided metal (e.g., copper (Cu)) clad laminate. As will be discussed below, exemplary embodiments involve processes for manufacturing/fabrication of thermoelectric devices/modules that enable flexibility thereof not only in terms of substrates but also in terms of thin films/thermoelectric legs/interconnects/packaging. Preferably, exemplary embodiments provide for thermoelectric devices/modules completely wrappable and bendable around other devices utilized in specific applications, as will be discussed below. Further, exemplary embodiments provide for manufactured/fabricated thermoelectric devices/modules that are each less than or equal to 100 μm in dimensional thickness.

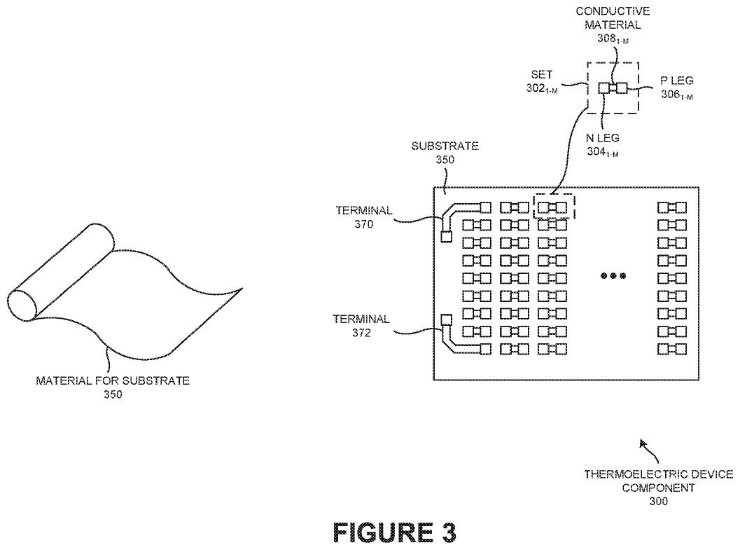

FIG. 3 shows a top view of a thermoelectric device component 300, according to one or more embodiments. Here, in one or more embodiments, a number of sets of N and P legs (e.g., sets 302_{1-M} including N legs 304_{1-M} and P legs 306_{1-M} therein) may be deposited on a substrate 350 (e.g., plastic, metal clad laminate) using a roll-to-roll process discussed above. FIG. 3 also shows a conductive material 308_{1-M} contacting both a set 302_{1-M} and substrate 350, according to one or more embodiments; an N leg 304_{1-M} and a P leg 306_{1-M} form a set 302_{1-M}, in which N leg 304_{1-M} and P leg 306_{1-M} electrically contact each other through conductive material 308_{1-M}. Terminals 370 and 372 may be electrically conductive leads to measure the potential difference generated by a thermoelectric device including thermoelectric device component 300.

Exemplary thermoelectric devices discussed herein may find utility in solar and solar thermal applications. As discussed above, traditional thermoelectric devices may have a size limitation and may not scale to a larger area. For example, a typical solar panel may have an area in the square meter (m²) range and the traditional thermoelectric device may have an area in the square inch range. A thermoelectric device in accordance with the exemplary embodiments may be of varying sizes and/or dimensions ranging from a few mm² to a few m².

Additionally, exemplary thermoelectric devices may find use in low temperature applications such as harvesting body heat in a wearable device, automotive devices/components and Internet of Things (IoT). Entities (e.g., companies, start-ups, individuals, conglomerates) may possess expertise to design and/or develop devices that require thermoelectric modules, but may not possess expertise in the fabrication and packaging of said thermoelectric modules. Alternately, even though the entities may possess the requisite expertise in the fabrication and packaging of the thermoelectric modules, the entities may not possess a comparative advantage with respect to the aforementioned processes.

In one scenario, an entity may create or possess a design pattern for a thermoelectric device. Said design pattern may be communicated to another entity associated with a thermoelectric platform to be tangibly realized as a thermoelectric device. It could also be envisioned that the another entity may provide training with regard to the fabrication processes to the one entity or outsource aspects of the fabrication processes to a third-party. Further, the entire set of processes involving Intellectual Property (IP) generation and manufacturing/fabrication of the thermoelectric device may be handled by a single entity. Last but not the least, the entity may generate the IP involving manufacturing/fabrication of the thermoelectric device and outsource the actual manufacturing/fabrication processes to the another entity.

All possible combinations of entities and third-parties are within the scope of the exemplary embodiments discussed herein.

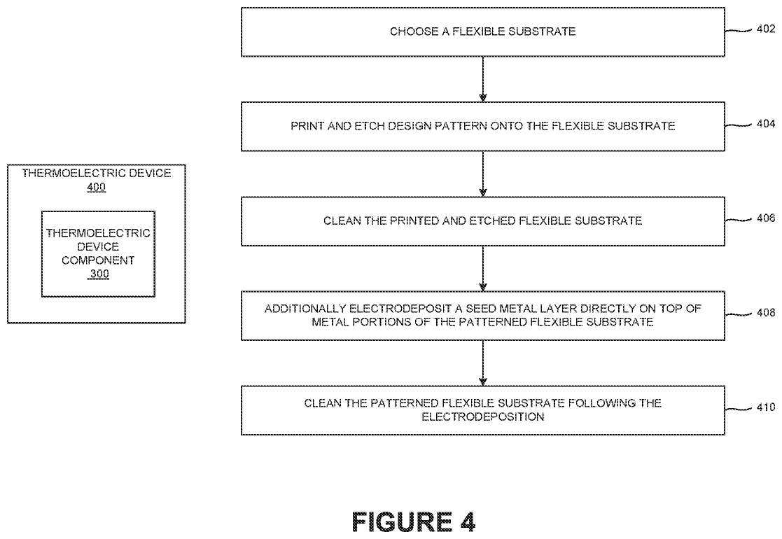

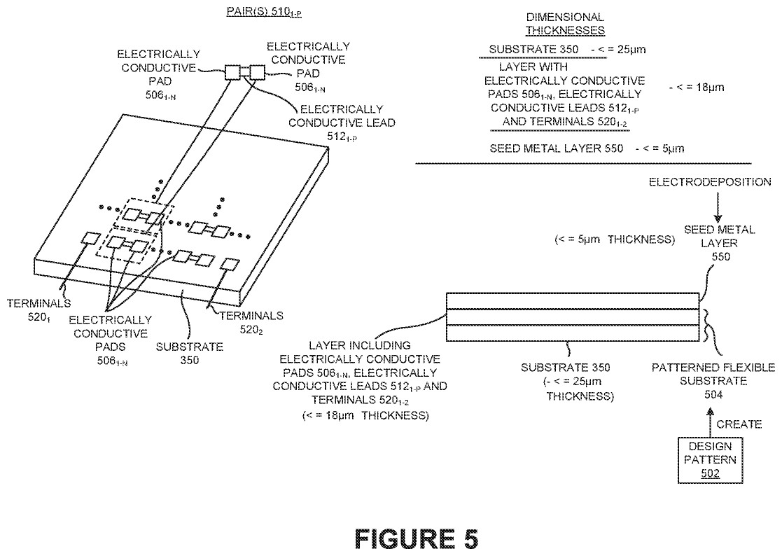

FIG. 4 shows the operations involved in realizing a patterned flexible substrate (e.g., patterned flexible substrate 504 shown in FIG. 5) of a thermoelectric device 400 as per a design pattern (e.g., design pattern 502 shown in FIG. 5), according to one or more embodiments. In one or more embodiments, operation 402 may involve choosing a flexible substrate (e.g., substrate 350) onto which, in operation 404, design pattern 502 may be printed (e.g., through inkjet printing, direct write, screen printing) and etched onto the flexible substrate. In one or more embodiments, a dimensional thickness of substrate 350 may be less than or equal to 25 μm.

Etching, as defined above, may refer to the process of removing (e.g., chemically) unwanted metal (say, Cu) from the patterned flexible substrate. In one example embodiment, a mask (e.g., a shadow mask) or a resist may be placed on portions of the patterned flexible substrate corresponding to portions of the metal that are to remain after the etch. Here, in one or more embodiments, the portions of the metal that remain on the patterned flexible substrate may be electrically conductive pads, electrically conductive leads and terminals formed on a surface of the patterned flexible substrate. FIG. 5 shows a patterned flexible substrate 504 including a number of electrically conductive pads 506_{1-N} formed thereon. Each electrically conductive pad 506_{1-N} may be a flat area of the metal that enables an electrical connection.

Also, FIG. 5 shows a majority set of the electrically conductive pads 506_{1-N} as including pairs 510_{1-P} of electrically conductive pads 506_{1-N} in which one electrically conductive pad 506_{1-N} may be electrically paired to another electrically conductive pad 506_{1-N} through an electrically conductive lead 512_{1-P} also formed on patterned flexible substrate 504; terminals 520₁₋₂ (e.g., analogous to terminals 370 and 372) may also be electrically conductive leads to measure the potential difference generated by the thermoelectric device/module fabricated based on design pattern 502. The aforementioned potential difference may be generated based on heat (or, cold) applied at an end of the thermoelectric device/module.

It should be noted that the configurations of the electrically conductive pads 506_{1-N}, electrically conductive leads 512_{1-P} and terminals 520₁₋₂ shown in FIG. 5 are merely for example purposes, and that other example configurations are within the scope of the exemplary embodiments discussed herein. It should also be noted that patterned flexible substrate 504 may be formed based on design pattern 502 in accordance with the printing and etching discussed above.

Example etching solutions employed may include but are not limited to ferric chloride and ammonium persulphate. Referring back to FIG. 4, operation 406 may involve cleaning the printed and etched flexible substrate. For example, acetone, hydrogen peroxide or alcohol may be employed therefor. Other forms of cleaning are within the scope of the exemplary embodiments discussed herein. In one or more embodiments, the aforementioned processes discussed in FIG. 4 may result in a dimensional thickness of electrically conductive pads 506_{1-N}, electrically conductive leads 512_{1-P} and terminals 520₁₋₂ being less than or equal to 18 μm.

The metal (e.g., Cu) finishes on the surface of patterned flexible substrate 504 may oxidize over time if left unprotected. As a result, in one or embodiments, operation 408 may involve additionally electrodepositing a seed metal layer 550 including Chromium (Cr), Nickel (Ni) and/or Gold (Au) directly on top of the metal portions (e.g., electrically conductive pads 506_{1-N}, electrically conductive leads 512_{1-P}, terminals 520₁₋₂) of patterned flexible substrate 504 following the printing, etching and cleaning. In one or more embodiments, a dimensional thickness of seed metal layer 550 may be less than or equal to 5 μm.

In one example embodiment, surface finishing may be employed to electrodeposit seed metal layer 550; the aforementioned surface finishing may involve Electroless Nickel Immersion Gold (ENIG) finishing. Here, a coating of two layers of metal may be provided over the metal (e.g., Cu) portions of patterned flexible substrate 504 by way of Au being plated over Ni. Ni may be the barrier layer between Cu and Au. Au may protect Ni from oxidization and may provide for low contact resistance. Other forms of surface finishing/electrodeposition may be within the scope of the exemplary embodiments discussed herein. It should be noted that seed metal layer 550 may facilitate contact of sputter deposited N-type thermoelectric legs (to be discussed below) and P-type thermoelectric legs (to be discussed below) thereto.

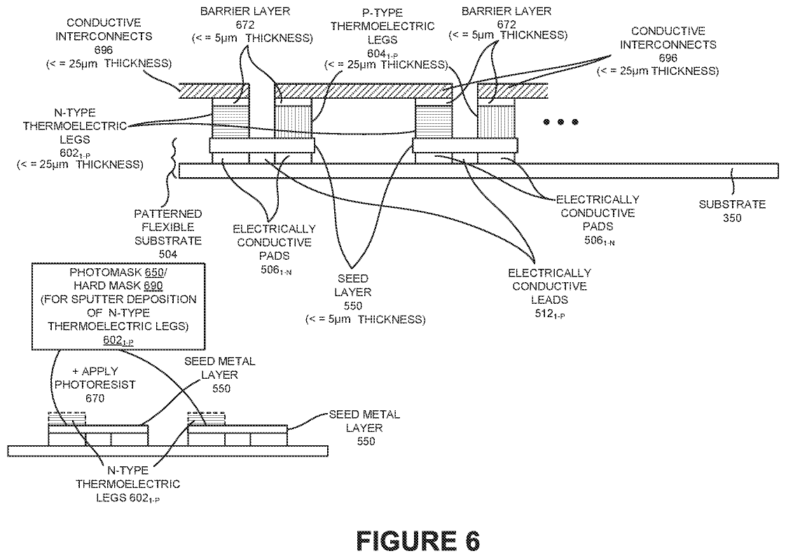

In one or more embodiments, operation 410 may then involve cleaning patterned flexible substrate 504 following the electrodeposition. FIG. 6 shows an N-type thermoelectric leg 602_{1-P} and a P-type thermoelectric leg 604_{1-P} formed on each pair 510_{1-P} of electrically conductive pads 506_{1-N}, according to one or more embodiments. In one or more embodiments, the aforementioned N-type thermoelectric legs 602_{1-P} and P-type thermoelectric legs 604_{1-P} may be formed on the surface finished patterned flexible substrate 504 (note: in FIG. 6, seed layer 550 is shown as surface finishing over electrically conductive pads 506_{1-N}/leads 512_{1-P}; terminals 520₁₋₂ have been omitted for the sake of clarity) of FIG. 5 through sputter deposition.

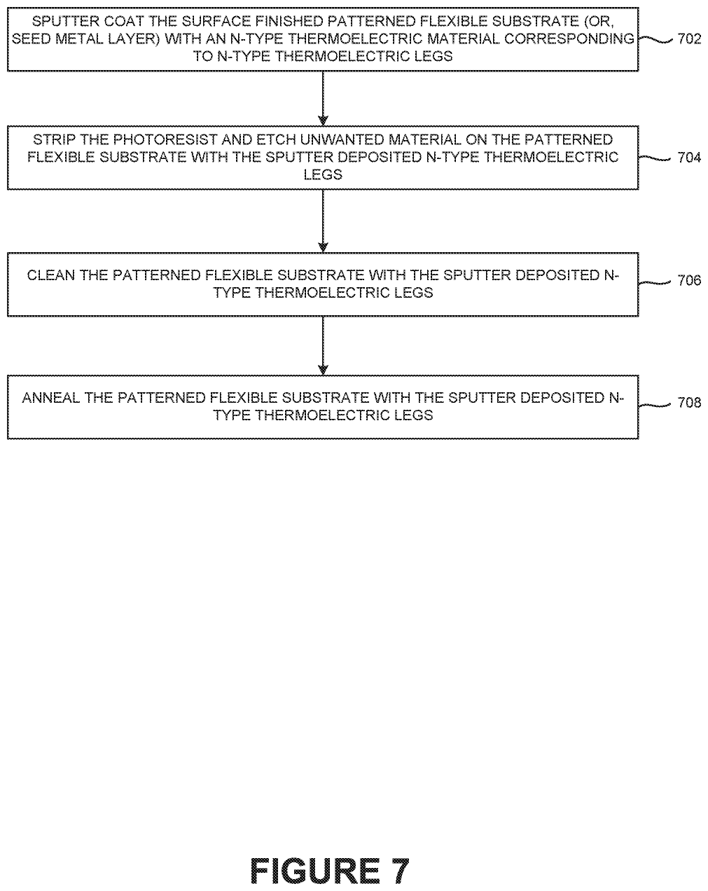

FIG. 7 details the operations involved in sputter deposition of N-type thermoelectric legs 602_{1-P} on the surface finished patterned flexible substrate 504 (or, seed metal layer 550) of FIG. 5, according to one or more embodiments. In one or more embodiments, the aforementioned process may involve a photomask 650 (shown in FIG. 6) on which patterns corresponding/complementary to the N-type thermoelectric legs 602_{1-P} may be generated. In one or more embodiments, a photoresist 670 (shown in FIG. 6) may be applied on the surface finished patterned flexible substrate 504, and photomask 650 placed thereon. In one or more embodiments, operation 702 may involve sputter coating (e.g., through magnetron sputtering) of the surface finished patterned flexible substrate 504 (or, seed metal layer 550) with an N-type thermoelectric material corresponding to N-type thermoelectric legs 602_{1-P}, aided by the use of photomask 650. The photoresist 670/photomask 650 functions are well understood to one skilled in the art; detailed discussion associated therewith has been skipped for the sake of convenience and brevity.

In one or more embodiments, operation 704 may involve stripping (e.g., using solvents such as dimethyl sulfoxide or alkaline solutions) of photoresist 670 and etching of unwanted material on patterned flexible substrate 504 with sputter deposited N-type thermoelectric legs 602_{1-P}. In one or more embodiments, operation 706 may involve cleaning the patterned flexible substrate 504 with the sputter deposited N-type thermoelectric legs 602_{1-P}; the cleaning process may be similar to the discussion with regard to FIG. 4.

In one or more embodiments, operation 708 may then involve annealing the patterned flexible substrate 504 with the sputter deposited N-type thermoelectric legs 602_{1-P}; the annealing process may be conducted (e.g., in air or vacuum) at 175° C. for 4 hours. In one or more embodiments, the annealing process may remove internal stresses and may contribute stability of the sputter deposited N-type thermoelectric legs 602_{1-P}. In one or more embodiments, a dimensional thickness of the sputter deposited N-type thermoelectric legs 602_{1-P} may be less than or equal to 25 μm.

It should be noted that P-type thermoelectric legs 604_{1-P} may also be sputter deposited on the surface finished pattern flexible substrate 504. The operations associated therewith are analogous to those related to the sputter deposition of N-type thermoelectric legs 602_{1-P}. Obviously, photomask 650 may have patterns corresponding/complementary to the P-type thermoelectric legs 604_{1-P} generated thereon. Detailed discussion associated with the sputter deposition of P-type thermoelectric legs 604_{1-P} has been skipped for the sake of convenience; it should be noted that a dimensional thickness of the sputter deposited P-type thermoelectric legs 604_{1-P} may also be less than or equal to 25 μm.

It should be noted that the sputter deposition of P-type thermoelectric legs 604_{1-P} on the surface finished patterned flexible substrate 504 may be performed after the sputter deposition of N-type thermoelectric legs 602_{1-P} thereon or vice versa. Also, it should be noted that various feasible forms of sputter deposition are within the scope of the exemplary embodiments discussed herein. In one or more embodiments, the sputter deposited P-type thermoelectric legs 604_{1-P} and/or N-type thermoelectric legs 602_{1-P} may include a material chosen from one of: Bismuth Telluride (Bi₂Te₃), Bismuth Selenide (Bi₂Se₃), Antimony Telluride (Sb₂Te₃), Lead Telluride (PbTe), Silicides, Skutterudites and Oxides.

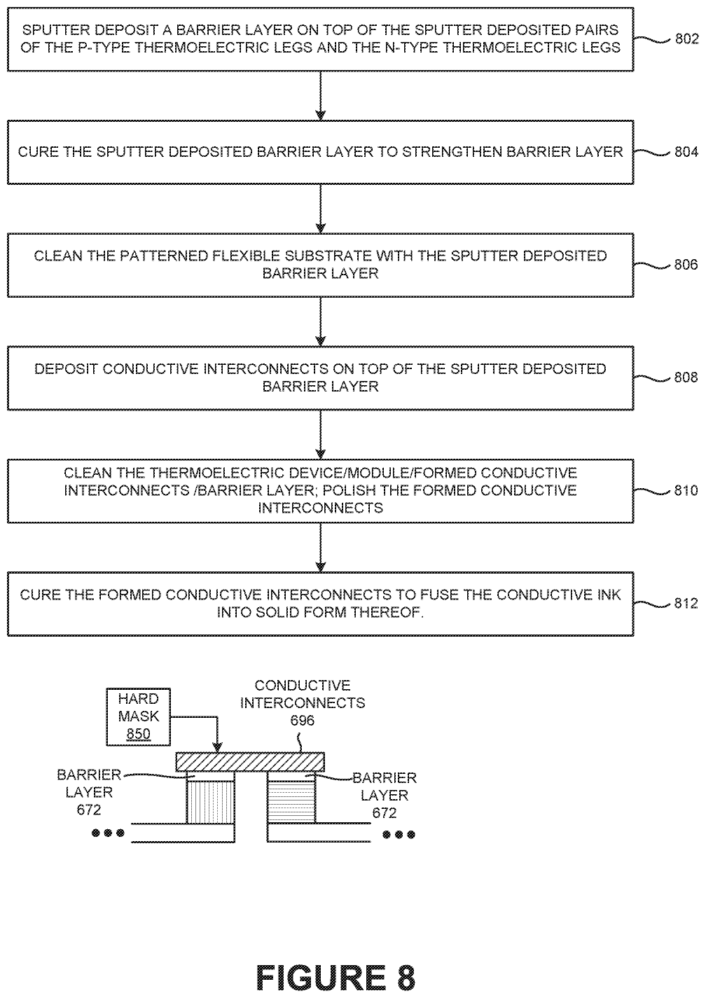

FIG. 8 details operations involved in deposition of a barrier layer 672 (refer to FIG. 6) on top of the sputter deposited pairs of P-type thermoelectric legs 604_{1-P} and N-type thermoelectric legs 602_{1-P} and forming conductive interconnects 696 on top of barrier layer 672, according to one or more embodiments.

In one or more embodiments, operation 802 may involve sputter depositing barrier layer 672 (e.g., film) on top of the sputter deposited pairs of the P-type thermoelectric legs 604_{1-P} and the N-type thermoelectric leg 602_{1-P} discussed above. In one or more embodiments, barrier layer 672 may be electrically conductive and may have a higher melting temperature than the thermoelectric material forming the P-type thermoelectric legs 604_{1-P} and the N-type thermoelectric legs 602_{1-P}. In one or more embodiments, barrier layer 672 may prevent corruption (e.g., through diffusion, sublimation) of one layer (e.g., the thermoelectric layer including the P-type thermoelectric legs 604_{1-P} and the N-type thermoelectric legs 602_{1-P}) by another layer. An example material employed as barrier layer 672 may include but is not limited to Cr, Ni or Au. Further, in one or more embodiments, barrier layer 672 may further aid metallization contact therewith (e.g., with conductive interconnects 696).

In one or more embodiments, a dimensional thickness of barrier layer 672 may be less than or equal to 5 μm. It is obvious that another photomask (not shown) analogous to photomask 650 may be employed to aid the patterned sputter deposition of barrier layer 672; details thereof have been skipped for the sake of convenience and clarity. In one or more embodiments, operation 804 may involve may involve curing barrier layer 672 at 175° C. for 4 hours to strengthen barrier layer 672. In one or more embodiments, operation 806 may then involve cleaning patterned flexible substrate 504 with barrier layer 672.

In one or more embodiments, operation 808 may involve depositing conductive interconnects 696 on top of barrier layer 672. In one example embodiment, the aforementioned deposition may be accomplished by screen printing silver (Ag) ink or other conductive forms of ink on barrier layer 672. Other forms of conductive interconnects 696 based on conductive paste(s) are within the scope of the exemplary embodiments discussed herein. As shown in FIG. 8, a hard mask 850 may be employed to assist the selective application of conductive interconnects 696 based on screen printing of Ag ink. In one example embodiment, hard mask 850 may be a stencil.

In one or more embodiments, the screen printing of Ag ink may contribute to the continued flexibility of the thermoelectric device/module and low contact resistance. In one or more embodiments, operation 810 may involve cleaning (e.g., using one or more of the processes discussed above) the thermoelectric device/module/formed conductive interconnects 696/barrier layer 672 and polishing conductive interconnects 696. In one example embodiment, the polishing may be followed by another cleaning process. In one or more embodiments, operation 812 may then involve curing conductive interconnects 696 at 175° C. for 4 hours to fuse the conductive ink into solid form thereof. In one or more embodiments, conductive interconnects 696 may have a dimensional thickness less than or equal to 25 μm.

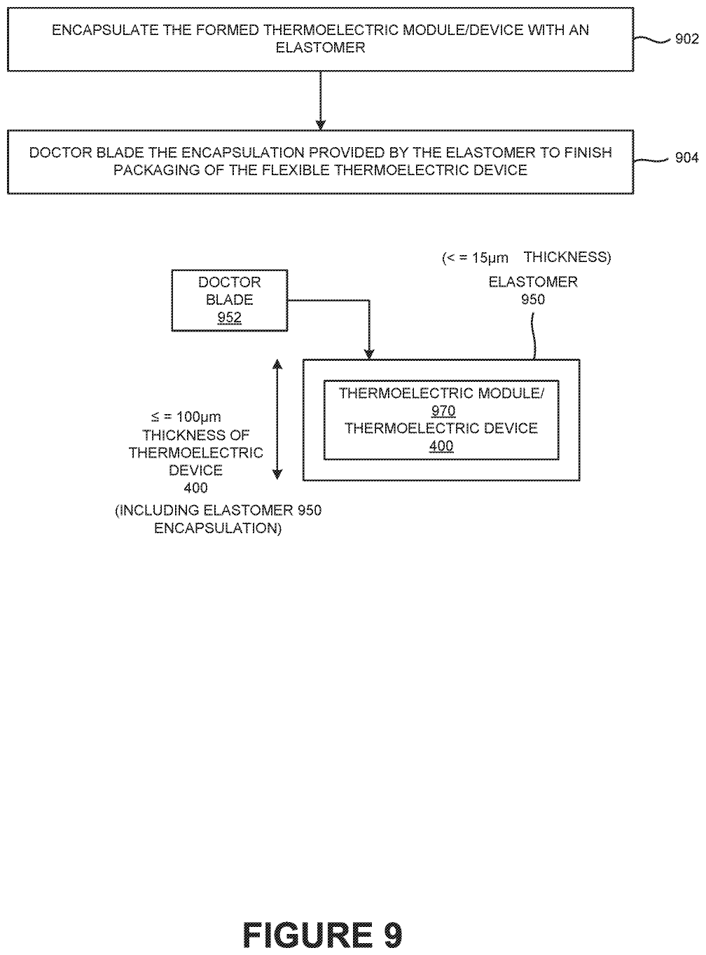

FIG. 9 details the operations involved in encapsulating the thermoelectric device (e.g., thermoelectric module 970)/module discussed above, according to one or more embodiments. In one or more embodiments, operation 902 may involve encapsulating the formed thermoelectric module (e.g., thermoelectric module 970)/device (with barrier layer 672 and conductive interconnects 696) with an elastomer 950 to render flexibility thereto. In one or more embodiments, as shown in FIG. 9, the encapsulation provided by elastomer 950 may have a dimensional thickness of less than or equal to 15 μm. In one or more embodiments, operation 904 may involve doctor blading (e.g., using doctor blade 952) the encapsulation provided by elastomer 950 to finish packaging of the flexible thermoelectric device/module discussed above.

In one or more embodiments, the doctor blading may involve controlling precision of a thickness of the encapsulation provided by elastomer 950 through doctor blade 952. In one example embodiment, elastomer 950 may be silicone. Here, said silicone may be loaded with nano-size aluminum oxide (Al₂O₃) powder to enhance thermal conductivity thereof to aid heat transfer across the thermoelectric module.

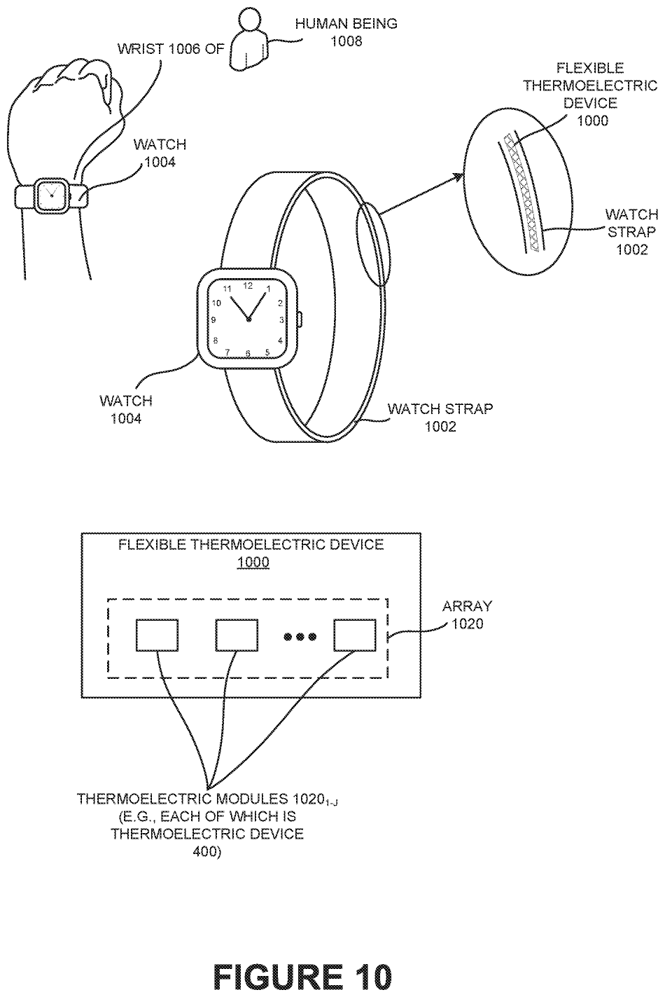

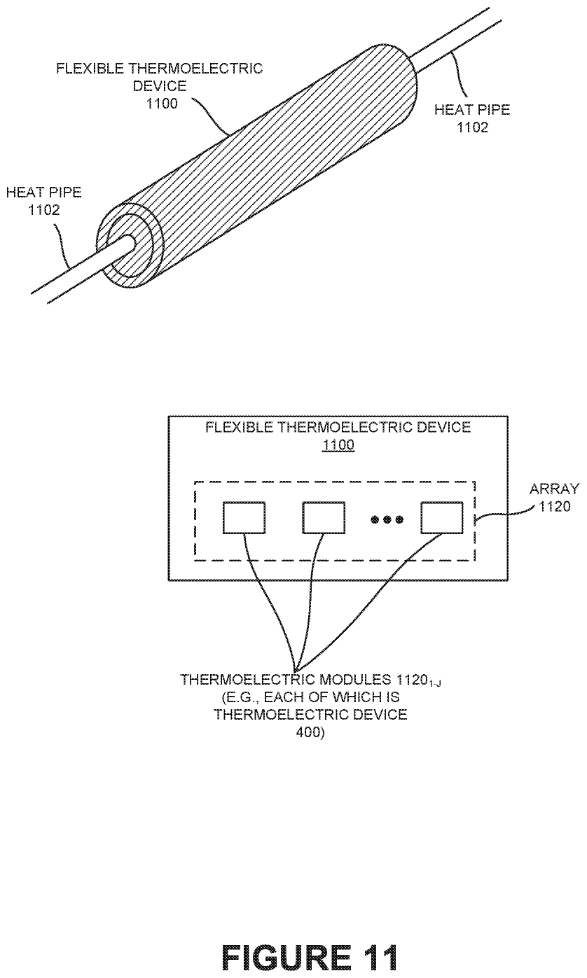

In one or more embodiments, as seen above, all operations involved in fabricating the thermoelectric device/module (e.g., thermoelectric device 400) render said thermoelectric device/module flexible. FIG. 10 shows a flexible thermoelectric device 1000 discussed herein embedded within a watch strap 1002 of a watch 1004 completely wrappable around a wrist 1006 of a human being 1008; flexible thermoelectric device 1000 may include an array 1020 of thermoelectric modules 1020_{1-J} (e.g., each of which is thermoelectric device 400) discussed herein. In one example embodiment, flexible thermoelectric device 1000 may serve to augment or substitute power derivation from a battery of watch 1004. FIG. 11 shows a flexible thermoelectric device 1100 discussed herein wrapped around a heat pipe 1102; again, flexible thermoelectric device 1100 may include an array 1120 of thermoelectric modules 1120_{1-J} (e.g., each of which is thermoelectric device 400) discussed herein. In one example embodiment, flexible thermoelectric device 1100 may be employed to derive thermoelectric power (e.g., through array 1120) from waste heat from heat pipe 1102.

It should be noted that although photomask 650 is discussed above with regard to deposition of N-type thermoelectric legs 602_{1-P} and a P-type thermoelectric legs 604_{1-P}, the aforementioned deposition may, in one or more other embodiments, involve a hard mask 690, as shown in FIG. 6. Further, it should be noted that flexible thermoelectric device 400/1000/1100 may be fabricated/manufactured such that the aforementioned device is completely wrappable and bendable around a system element (e.g., watch 1004, heat pipe 1102) that requires said flexible thermoelectric device 400/1000/1100 to perform a thermoelectric power generation function using the system element.

The abovementioned flexibility of thermoelectric device 400/1000/1100 may be enabled through proper selection of flexible substrates (e.g., substrate 350) and manufacturing techniques/processes that aid therein, as discussed above. Further, flexible thermoelectric device 1000/1100 may be bendable 360° such that the entire device may completely wrap around the system element discussed above. Still further, in one or more embodiments, an entire dimensional thickness of the flexible thermoelectric module (e.g., flexible thermoelectric device 400) in a packaged form may be less than or equal to 100 μm, as shown in FIG. 9.

Last but not the least, as the dimensions involved herein are restricted to less than or equal to 100 μm, the flexible thermoelectric device/module discussed above may be regarded as being thin-film based (e.g., including processes involved in fabrication thereof).

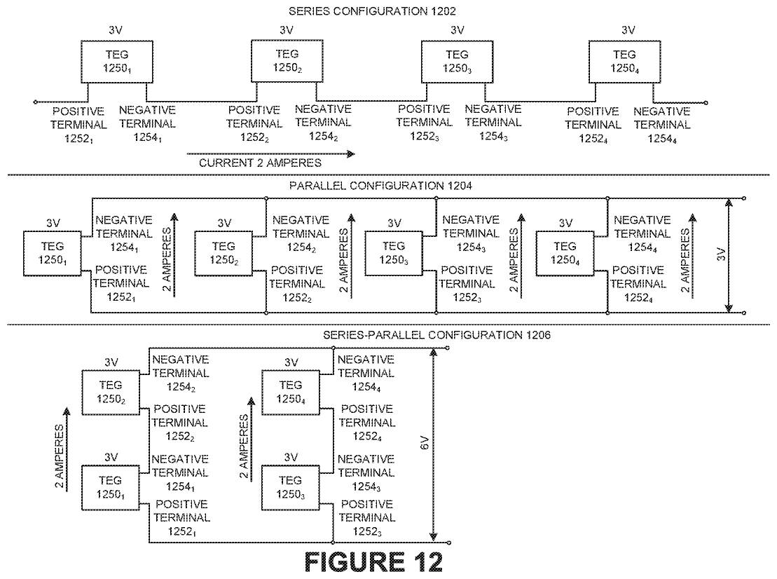

FIG. 12 shows example wiring configurations of an example set of four equivalent thermoelectric generators (TEGs) 1250₁₋₄ including a series configuration 1202, a parallel configuration 1204 and a series-parallel configuration 1206. TEGs are known to one skilled in the art. Detailed discussion associated therewith has been skipped for the sake of convenience and brevity. Each TEG 1250₁₋₄ may be assumed to produce a hypothetical 3 volts and 2 amperes. In series configuration 1202, a negative terminal 1254₁ of the first TEG 1250₁ may be electrically connected to a positive terminal 1252₂ of the second TEG 1250₂, a negative terminal 1254₂ of the second TEG 1250₂ may be electrically connected to a positive terminal 1252₃ of the third TEG 1250₃, and a negative terminal 1254₃ of the third TEG 1250₃ may be electrically connected to a positive terminal 1252₄ of the fourth TEG 1250₄. The voltage between a positive terminal 1252₁ of the first TEG 1250₁ and a negative terminal 1254₄ of the fourth TEG 1250₄ may be the sum of voltages across terminals of each TEG 1250₁₋₄, i.e., 3+3+3+3=12 volts, while the current flowing in series configuration 1202 may be the same for each TEG 1250₁₋₄, i.e., 2 amperes. Therefore, the power output of series configuration 1202 may be 24 watts (W).

In parallel configuration 1204, positive terminals 1252₁₋₄ of TEGs 1250₁₋₄ may be electrically connected together and negative terminals 1254₁₋₄ of TEGs 1250₁₋₄ may be electrically connected together. The voltage between the electrically connected positive terminals 1252₁₋₄ and the electrically connected negative terminals 1254₁₋₄ in parallel configuration 1204 may be the same 3 volts, while the currents add up to 2+2+2+2=8 amperes. Therefore, the power output of parallel configuration 1204 may, again, be 24 W.

In series-parallel configuration 1206, which is a combination of series configuration 1202 and parallel configuration 1204, the negative terminal 1254₁ of the first TEG 1250₁ may be electrically connected to the positive terminal 1252₂ of the second TEG 1250₂. Similarly, the negative terminal 1254₃ of the third TEG 1250₃ may be electrically connected to the positive terminal 1252₄ of the fourth TEG 1250₄. In addition, the positive terminal 1252₁ and the positive terminal 1252₃ of the first TEG 1250₁ and the third TEG 1250₃ respectively may be electrically connected together and the negative terminal 1254₂ and the negative terminal 1254₄ of the second TEG 1250₂ and the fourth TEG 1250₄ respectively may be electrically connected together. Here, the current through each of the first TEG 1250₁-second TEG 1250₂ branch and the third TEG 1250₃-fourth TEG 1250₄ branch may be 2 amperes. These currents may add up to 4 amperes. The voltage across each of the aforementioned branches may be 3+3=6 volts. Thus, the power output of series-parallel configuration 1206 may, again, be 24 W.

The current state-of-the-art TEGs (e.g., TEGs 1250₁₄) may be unit devices that may be electrically connected either in series or in parallel. Typical bulk TEG modules may be limited in size due to rigidity of substrates and longer dimensions of thermoelectric legs thereof. Thus, the aforementioned bulk TEG modules may almost always be standalone devices where N and P thermoelectric elements/legs are connected in series or in parallel on rigid substrates (e.g., Aluminum Oxide (Al₂O₃)). Adding cells/pairs/series of N and P legs in a bulk TEG module may increase the series resistance thereof.

As the series resistance goes up, an output current of the bulk TEG module drops. At low temperature differences between a hot end and a cold end of the bulk TEG module, there may not be enough of an output voltage, which, coupled with the negligible current because of high module resistance, causes the bulk TEG module to not work. Even though thermoelectric modules may be designed taking the aforementioned issues into account, no bulk TEG module more than a couple of inches in dimensional length may typically be available in the market. This may mainly be due to process restrictions and electrical output limitations at low temperature differences.

In one or more embodiments, manufacturing a large (e.g., 1 square meter) area thermoelectric module may require organization of various thermoelectric cells/sets/pairs of N legs and P legs into clusters, and subsequent grouping of the aforementioned clusters into series and parallel design configurations (to be discussed below) to manage overall resistance, and, thereby, output current.

FIG. 3 shows a single thermoelectric module (e.g., thermoelectric device component 300) where each set 302_{1-M} of N leg 304_{1-M} and P leg 306_{1-M} is electrically coupled to another set 302_{1-M} in series, according to one or more embodiments. As seen therein, the series configuration may involve an N leg 304_{1-M} of one set 302_{1-M} being electrically connected to a P leg 306_{1-M} of a neighboring set 302_{1-M}. The P leg 306_{1-M} of the one set 302_{1-M} may be electrically connected to an N leg 304_{1-M} of a previous set 302_{1-M}. It is also possible to envision a configuration where an N leg 304_{1-M} of one set 302_{1-M} may be electrically connected to an N leg 304_{1-M} of a neighboring set 302_{1-M}. Here, the P leg 306_{1-M} of the one set 302_{1-M} may be electrically connected to a P leg 306_{1-M} of a previous set 302_{1-M}. The aforementioned N-N and P-P thermoelectric leg electrical connections between sets 302_{1-M} may be a parallel configuration of thermoelectric legs within the single thermoelectric module.

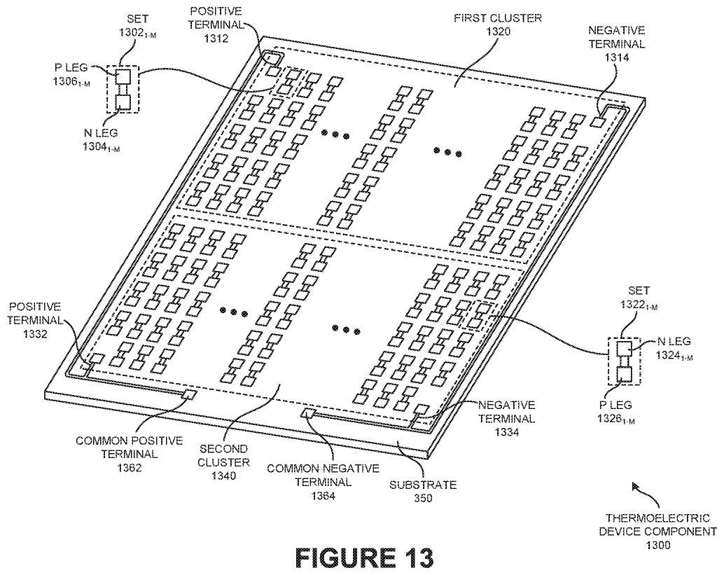

FIG. 13 shows a two cluster series-parallel configuration of a thermoelectric device component 1300 (analogous to thermoelectric device component 300), according to one or more embodiments. In one or more embodiments, thermoelectric device component 1300 may include a first cluster 1320 in which each set 1302_{1-M} (of sets 1302_{1-M}) of N leg 1304_{1-M} and P leg 1306_{1-M} may be electrically connected to another set 1302_{1-M} in series, and a second cluster 1340 in which each set 1322_{1-M} (of sets 1322_{1-M}) of N leg 1324_{1-M} and P leg 1326_{1-M} may be electrically connected to another set 1322_{1-M} in series. It is obvious that set 1302_{1-M} and set 1322_{1-M} may be analogous to set 302_{1-M} of FIG. 3, and that the thermoelectric legs of sets 1302_{1-M} and sets 1322_{1-M} may be deposited on pairs 510_{1-P} of electrically conductive pads 506_{1-N} (see FIG. 5). All concepts associated with FIGS. 1-11 are applicable to embodiments associated with FIG. 12 onward.

It should be noted that first cluster 1320 and second cluster 1340 may be distributed across substrate 350 (or, patterned flexible substrate 504). Now, in one or more embodiments, first cluster 1320 may be electrically connected to second cluster 1340 in parallel, as shown in FIG. 13. In other words, a positive terminal 1312 of first cluster 1320 may be electrically connected to a positive terminal 1332 of second cluster 1340 to realize a common positive terminal 1362 and a negative terminal 1314 of first cluster 1320 may be electrically connected to a negative terminal 1334 of second cluster 1340 to realize a common negative terminal 1364. In one or more embodiments, an output voltage may be measurable across common positive terminal 1362 and common negative terminal 1364, thereby rendering utilization thereof possible.

It is possible to envision first cluster 1320 and second cluster 1340 where sets (1302_{1-M}, 1322_{1-M}) of legs are electrically connected to one another in parallel (N-N and P-P, as discussed above) instead of series. In one or more other embodiments, first cluster 1320 and second cluster 1340 may be electrically coupled to one another in series instead of in parallel as in FIG. 13. Here, negative terminal 1314 of first cluster 1320 may be electrically connected to positive terminal 1332 of second cluster 1320, and an output voltage may be measurable across positive terminal 1312 of first cluster 1320 and negative terminal 1334 of second cluster 1320. In one or more embodiments, the series or parallel electrical connections may be dictated by output requirements (e.g., overall resistance, output current) corresponding to temperature differences between a hot end and a cold end of thermoelectric device component 1300. The aforementioned variations are within the scope of the exemplary embodiments discussed herein.

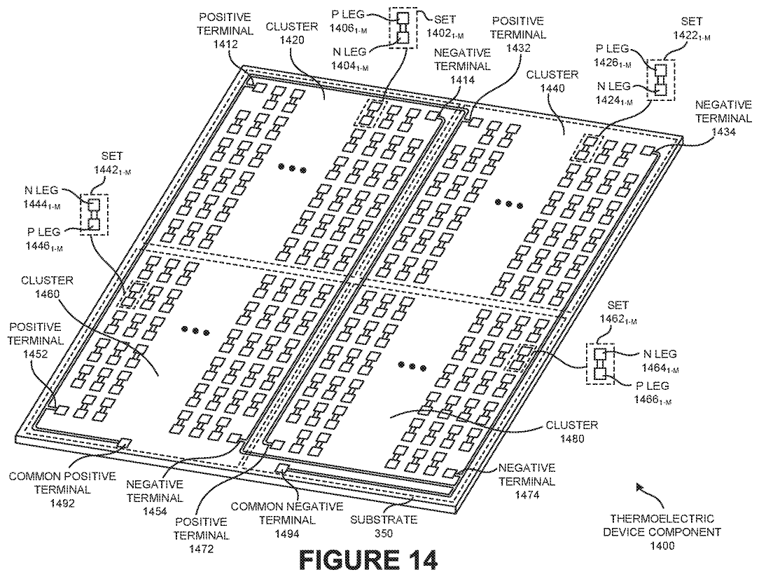

FIG. 14 shows a four cluster series-parallel configuration of a thermoelectric device component 1400 (analogous to thermoelectric device component 300), according to one or more embodiments. Again, each of the four clusters (1420, 1440, 1460 and 1480) may include sets (1402_{1-M}, 1422_{1-M}, 1442_{1-M} and 1462_{1-M}) of N legs (1404_{1-M}, 1424_{1-M}, 1444_{1-M} and 1464_{1-M}) and P legs (1406_{1-M}, 1426_{1-M}, 1446_{1-M} and 1466_{1-M}) in which one set (1402_{1-M}, 1422_{1-M}, 1442_{1-M} and 1462_{1-M}) may be electrically connected to another set (1402_{1-M}, 1422_{1-M}, 1442_{1-M} and 1462_{1-M}) in series. Again, it is obvious that each of the sets (1402_{1-M}, 1422_{1-M}, 1442_{1-M} and 1462_{1-M}) may be analogous to set 302_{1-M} of FIG. 3, and that the thermoelectric legs of the aforementioned sets (1402_{1-M}, 1422_{1-M}, 1442_{1-M} and 1462_{1-M}) may be deposited on pairs 510_{1-P} of electrically conductive pads 506_{1-N} (see FIG. 5).

Again, it should be noted that each of the four clusters (1420, 1440, 1460 and 1480) may be distributed across substrate 350 (or, patterned flexible substrate 504). Again, in one or more embodiments, each cluster (1420, 1440, 1460 and 1480) may be electrically connected to one another in parallel, as shown in FIG. 14. In other words, positive terminals (1412, 1432, 1452 and 1472) of the clusters (1420, 1440, 1460 and 1480) may be electrically connected to one another to realize a common positive terminal 1492 and negative terminals (1414, 1434, 1454 and 1474) of the clusters (1420, 1440, 1460 and 1480) may be electrically connected to one another to realize a common negative terminal 1494. In one or more embodiments, an output voltage may be measurable across common positive terminal 1492 and common negative terminal 1494, thereby rendering utilization thereof possible.

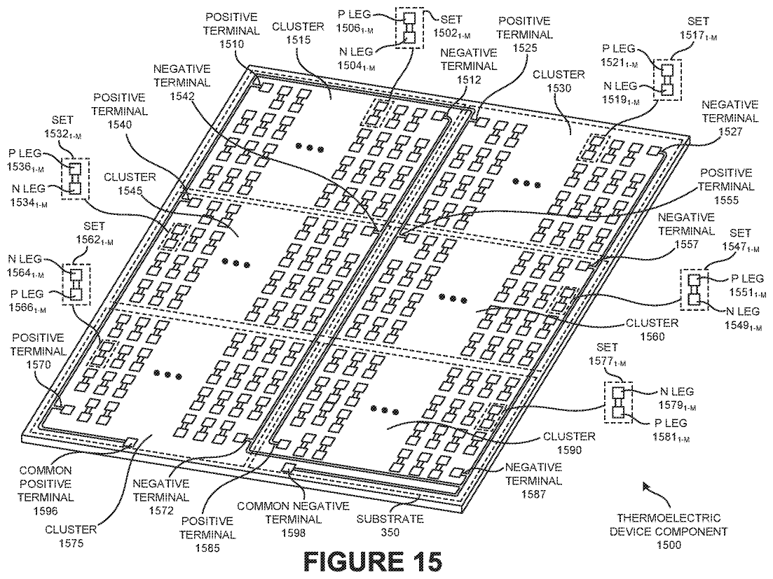

FIG. 15 shows a six cluster series-parallel configuration of a thermoelectric device component 1500 (analogous to thermoelectric device component 300), according to one or more embodiments. Yet again, each of the six clusters (1515, 1530, 1545, 1560, 1575 and 1590) may include sets (1502_{1-M}, 1517_{1-M}, 1532_{1-M}, 1547_{1-M}, 1562_{1-M} and 1577_{1-M}) of N legs (1504_{1-M}, 1519_{1-M}, 1534_{1-M}, 1549_{1-M}, 1564_{1-M} and 1579_{1-M}) and P legs (1506_{1-M}, 1521_{1-M}, 1536_{1-M}, 1551_{1-M}, 1566_{1-M} and 1581_{1-M}) in which one set (1502_{1-M}, 1517_{1-M}, 1532_{1-M}, 1547_{1-M}, 1562_{1-M} and 1577_{1-M}) may be electrically connected to another set (1502_{1-M}, 1517_{1-M}, 1532_{1-M}, 1547_{1-M}, 1562_{1-M} and 1577_{1-M}) in series. Again, it is obvious that each of the sets (1502_{1-M}, 1517_{1-M}, 1532_{1-M}, 1547_{1-M}, 1562_{1-M} and 1577_{1-M}) may be analogous to set 302_{1-M} of FIG. 3, and that the thermoelectric legs of the aforementioned sets (1502_{1-M}, 1517_{1-M}, 1532_{1-M}, 1547_{1-M}, 1562_{1-M} and 1577_{1-M}) may be deposited on pairs 510_{1-P} of electrically conductive pads 506_{1-N} (see FIG. 5).

Again, it should be noted that each of the six clusters (1515, 1530, 1545, 1560, 1575 and 1590) may be distributed across substrate 350 (or, patterned flexible substrate 504). Again, in one or more embodiments, each cluster (1515, 1530, 1545, 1560, 1575 and 1590) may be electrically connected to one another in parallel, as shown in FIG. 15. In other words, positive terminals (1510, 1525, 1540, 1555, 1570 and 1585) of the clusters (1515, 1530, 1545, 1560, 1575 and 1590) may be electrically connected to one another to realize a common positive terminal 1596 and negative terminals (1512, 1527, 1542, 1557, 1572 and 1587) of the clusters (1515, 1530, 1545, 1560, 1575 and 1590) may be electrically connected to one another to realize a common negative terminal 1598. In one or more embodiments, an output voltage may be measurable across common positive terminal 1596 and common negative terminal 1598, thereby rendering utilization thereof possible.

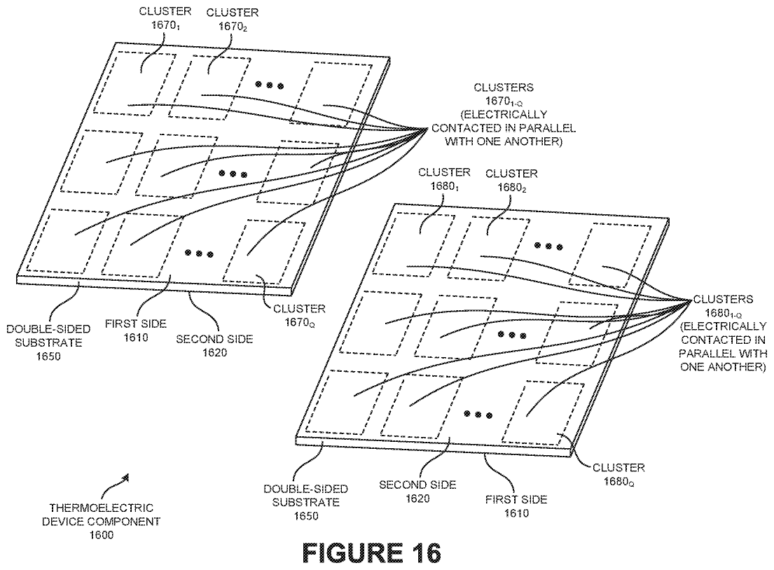

FIG. 16 shows a thermoelectric device component 1600, according to one or more embodiments. Here, in one or more embodiments, both sides (e.g., a first side 1610 and a second side 1620) of a double-sided substrate 1650 (analogous to substrate 350, or, flexible patterned substrate 504) may include clusters (e.g., clusters 1670_{1-Q}, clusters 1680_{1-Q}) of thermoelectric legs in series that are electrically connected in parallel to one another. In other words, clusters 1670_{1-Q} may be coupled in parallel to one another on first side 1610 and clusters 1680_{1-Q} may be coupled in parallel to one another on second side 1620. In one or more embodiments, the aforementioned two-sidedness may involve deposition of thermoelectric legs on electrically conductive pads discussed above with reference to FIGS. 1-11 on both sides of double-sided substrate 1650.

In one or more embodiments, utilization of both sides (or, both surfaces) of double-sided substrate 1650 may approximately double performance by enabling two thermoelectric device sub-components (one on either side) of thermoelectric device component 1600 utilize a given temperature difference between the sides (e.g., first side 1610 and second side 1620) instead of merely one. In one or more embodiments, as two sets of clusters of thermoelectric legs (one on top of first side 1610 and another on top of second side 1620) provide for double the effective thermoelectric thickness compared to merely one set, the performance of a thermoelectric device incorporating thermoelectric device component 1600 may approximately be doubled for a given temperature difference between the sides.

Again, it is possible to envision clusters of the thermoelectric device components 1300-1600 where sets of legs are electrically connected to one another in parallel instead of series. Also, it is possible to envision one cluster of a thermoelectric device component 1300-1600 being electrically connected to another cluster thereof in series instead of in parallel. Again, in one or more embodiments, the series or parallel electrical connections may be dictated by output requirements (e.g., overall resistance, output current) corresponding to temperature differences between a hot end and a cold end of thermoelectric device component 1300-1600. The aforementioned variations are within the scope of the exemplary embodiments discussed herein. Parallel electrical connections between sets of thermoelectric legs within a cluster and series electrical connections between a cluster are obvious in view of the connections illustrated in FIGS. 13-16. Therefore, explicit illustration thereof has been skipped for the sake of convenience, clarity and brevity.

It is clear that the embodiments discussed with regard to FIGS. 13-16 are generalizable to any number of clusters (e.g., Q clusters). Within a cluster, there may be any number of sets of thermoelectric legs (e.g., 2 to any large number). The number of sets of thermoelectric legs may vary across clusters on a substrate (e.g., substrate 350). In one or more embodiments, the clusterization discussed above in thermoelectric device components 1300-1600 may lead to increased output (e.g., output current) compared to a bulk TEG module where clusterization is limited. In one or more embodiments, the clusterization may also allow for increased power densities within an area of substrate 350. Moreover, in one or more embodiments, all advantages including advantages of flexibility, size and scalability discussed above with regard to FIGS. 1-11 may also be applicable to the embodiments of FIGS. 13-16. These advantages of flexibility, size and scalability, in addition to the processes involved, may enable large-scale clusterization and inclusion of a large number of sets of thermoelectric legs within thermoelectric device component 1300-1600.

Additionally, it should be noted that the number of clusters and the number of sets of thermoelectric legs within a cluster may vary across two surfaces/sides of double-sided substrate 1650. Also, in one or more embodiments, one cluster may include a different thermoelectric material compared to another cluster on a substrate 350/double-sided substrate 1650. Further, it should be noted that pairs 510_{1-P} corresponding to the thermoelectric legs of each individual cluster may be deposited (e.g., simultaneously) using the processes discussed above. All reasonable variations are within the scope of the exemplary embodiments discussed herein.

Approximately 20-50% of energy used across the world may be lost in industrial operations through hot exhaust gases, heat losses from radiation, cooling water etc. Assuming a world energy consumption of 200,000 Terawatt-hour (TWh), even if 5% of the aforementioned energy is recovered at $50/Megawatt hour (MWh), costs associated therewith may escalate to half a trillion dollars. Recovering energy from waste heat and emissions may be disadvantaged by the lack of economical methods therefor and the complexity of available solutions.

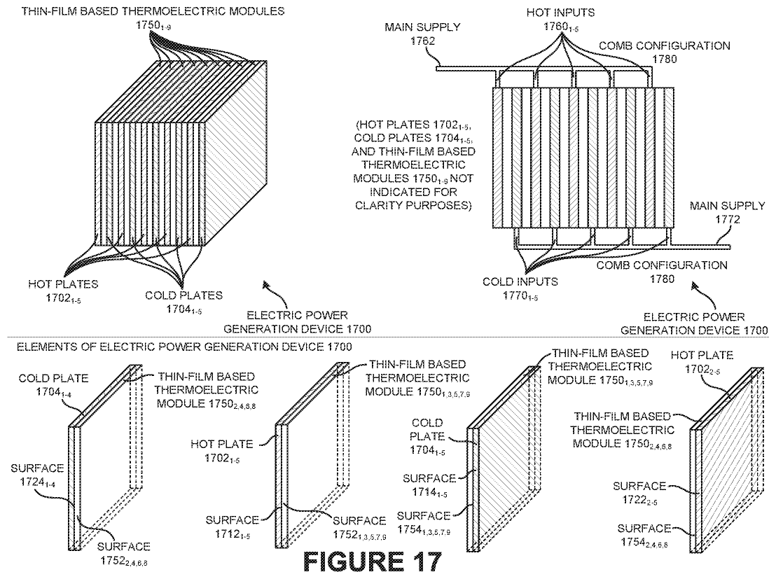

FIG. 17 shows an electric power generation device 1700, according to one or more embodiments. In one or more embodiments, electric power generation device 1700 may include alternating hot plates 1702₁₋₅ and cold plates 1704₁₋₅ arranged parallel to one another such that a surface 1712₁₋₅ of a hot plate 1702₁₋₅ is configured face a corresponding surface 1714₁₋₅ of a neighboring cold plate 1704₁₋₅. In one or more embodiments, in accordance therewith, a surface 1722₂₋₅ of hot plate 1702₂₋₅ may be configured to face a corresponding surface 1724₁₋₄ of a neighboring cold plate 1704₁₋₄. In one or more embodiments, hot plates 1702₁₋₅ may be associated with a “hot” end of a thermoelectric system formed in electric power generation device 1700 and cold plates 1704₁₋₅ may be associated with a “cold” end of the thermoelectric system formed therein.

In one or more embodiments, hot plates 1702₁₋₅ may be made of steel, a ceramic material and/or anodized aluminum. For example, all hot plates 1702₁₋₅ may be made of steel, the ceramic material or anodized aluminum or some hot plates 1702₁₋₅ may be made of steel/ceramic material and some hot plates 1702₁₋₅ made of anodized aluminum. Anodizing aluminum is known to one skilled in the art. Detailed discussion associated therewith has been skipped for the sake of convenience and clarity. Similarly, in one or more embodiments, cold plates 1704₁₋₅ may also be made of steel, a ceramic material and/or anodized aluminum. Again, for example, all cold plates 1704₁₋₅ may be made of steel, the ceramic material or anodized aluminum or some cold plates 1704₁₋₅ may be made of steel/ceramic material and some cold plates 1704₁₋₅ made of anodized aluminum. Anodizing aluminum may render surfaces of hot plates 1702₁₋₅/cold plates 1704₁₋₅ relatively non-reactive with thermoelectric modules (to be discussed below).

In some embodiments, hot plates 1702₁₋₅ (or even cold plates 1704₁₋₅) may also be painted (e.g., black) to increase heat absorption therein and provide for insulation. In one or more embodiments, in between each neighboring hot plate 1702₁₋₅ and cold plate 1704₁₋₅, a thin-film based thermoelectric module 1750₁₋₉ (e.g., thermoelectric module 970) may be placed in parallel to the each neighboring hot plate 1702₁₋₅ and cold plate 1704₁₋₅ such that a surface 1752_{1,3,5,7,9} of thin-film based thermoelectric module 1750_{1,3,5,7,9} is configured to contact (e.g., physically and thermally) a corresponding surface 1712₁₋₅ of a hot plate 1702₁₋₅ and a surface 1752_{2,4,6,8} of thin-film based thermoelectric module 1750_{2,4,6,8} is configured to contact a corresponding surface 1724₁₋₄ of a cold plate 1704₁₋₄. Also, in one or more embodiments, in accordance therewith, a surface 1754_{1,3,5,7,9} of thin-film based thermoelectric module 1750_{1,3,5,7,9} may be configured to contact a corresponding surface 1714₁₋₅ of a cold plate 1704₁₋₅ and a surface 1754_{2,4,6,8} of thin-film based thermoelectric module 1750_{2,4,6,8} may be configured to contact a corresponding surface 1722₂₋₅ of a hot plate 1702₂₋₅.

It should be noted that thin-film based thermoelectric module 1750₁₋₉ may represent any of the embodiments of FIGS. 3-9 and FIGS. 13-16. In other words, thin-film based thermoelectric module 1750₁₋₉ may be any of the modules discussed with reference to FIGS. 3-9 (encapsulated and non-encapsulated versions of thermoelectric modules) and FIGS. 13-16 (including the embodiments of FIG. 16 where both sides of double-sided substrate 1650 have thermoelectric legs deposited thereon; it should be noted, in the embodiment of FIG. 16, both first side 1610 and second side 1620 may have thermoelectric legs deposited thereon analogous to the embodiment of FIG. 3). Each side/surface (with or without thermoelectric legs; with or without the encapsulation discussed above) of substrate 350 may contact a hot plate 1702₁₋₅ or a cold plate 1704₁₋₅.

In one or more embodiments, each hot plate 1702₁₋₅ may be supplied with a hot input 1760₁₋₅ (“hot” end of the corresponding thin-film based thermoelectric module 1750₁₋₉ in contact therewith) and each cold plate 1704₁₋₅ may be supplied with a cold input 1770₁₋₅ (“cold” end of the corresponding thin-film based thermoelectric module 1750₁₋₉ in contact therewith). In one or more embodiments, hot inputs 1760₁₋₅ may be hot water (e.g., water at 100° C.), hot steam and/or another hot liquid (e.g., ethylene glycol) carried through pipes/tubes. In one or more other embodiments, hot inputs 1760₁₋₅ may be hot waste flue gas from a furnace, a boiler and/or a power plant. It may be possible for the aforementioned hot steam, hot water and/or the another hot liquid to be waste products from industrial processes. To generalize, in one or more embodiments, hot inputs 1760₁₋₅ and cold inputs 1770₁₋₅ may be fluids at higher temperature(s) and lower temperature(s) respectively. Other forms of hot inputs 1760₁₋₅ and mechanisms of distribution thereof are within the scope of the exemplary embodiments discussed herein.

In one or more embodiments, cold inputs 1770₁₋₅ may be water at room temperature or any temperature considerably less than the temperature of the content of hot inputs 1760₁₋₅; the aforementioned cold inputs 1770₁₋₅ may be carried by tubes/pipes. Again, other forms of cold inputs 1770₁₋₅ and mechanisms of distribution thereof are within the scope of the exemplary embodiments discussed herein. FIG. 17 shows each of hot inputs 1760₁₋₅ and cold inputs 1770₁₋₅ being applied to hot plates 1702₁₋₅ and cold plates 1704₁₋₅ in a comb configuration 1780 of pipes/tubes whereby a main supply (e.g., main supply 1762 for hot inputs 1760₁₋₅, main supply 1772 for cold inputs 1770₁₋₅) forms a frame of a comb from which a branch carrying a hot input 1760₁₋₅/a cold input 1770₁₋₅ is fed into each hot plate 1702₁₋₅/each cold plate 1704₁₋₅ as a tooth of the comb. Here, the main supply (e.g., main supply 1762) for hot inputs 1760₁₋₅ may come from one end (e.g., an end closest to the first hot plate 1702₁) of electric power generation device 1700 and the main supply (e.g., main supply 1772) for cold inputs 1770₁₋₅ may come from another end (e.g., an end closest to the last cold plate 1704₅) thereof. It should be noted that other configurations of hot inputs 1760₁₋₅ and cold inputs 1770₁₋₅ are within the scope of the exemplary embodiments discussed herein.

For example, main supply 1762 and main supply 1772 may originate from the same end of electric power generation device 1700 in one or more alternate embodiments; alternately, main supply 1762 may come from the end closest to the last cold plate 1704₅ while main supply 1772 may come from the end closest to the first hot plate 1702₁. Each of hot inputs 1760₁₋₅ and cold inputs 1770₁₋₅ may have separate sources associated therewith. Or some of hot inputs 1760₁₋₅/cold inputs 1770₁₋₅ may have a common source while others may have distinct sources. All configurations of piping/tubing and supplies of hot inputs 1760₁₋₅ and cold inputs 1770₁₋₅ are within the scope of the exemplary embodiments discussed herein.

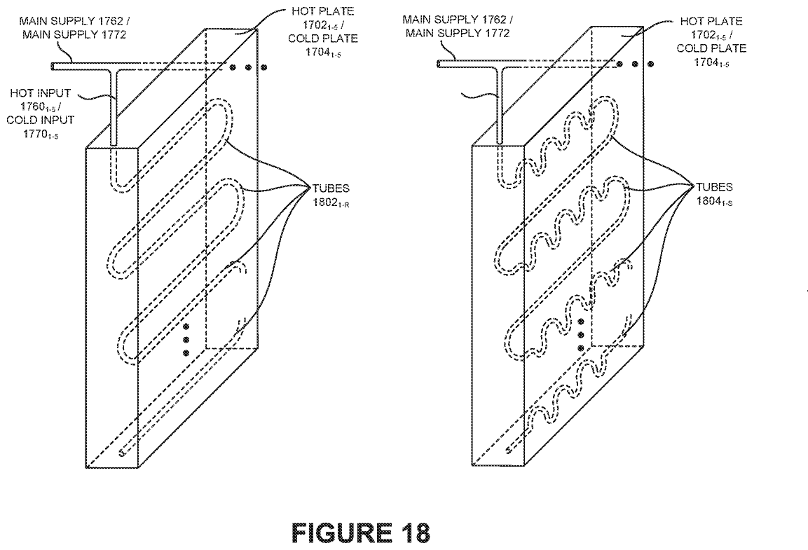

Obviously, in one or more embodiments, hot inputs 1760₁₋₅ and cold inputs 1770₁₋₅ may physically and thermally contact the corresponding hot plates 1702₁₋₅ and cold plates 1704₁₋₅. FIG. 18 shows examples of channelization of a hot input 1760₁₋₅/cold input 1770₁₋₅ into a corresponding hot plate 1702₁₋₅/cold plate 1704₁₋₅. In a first example, the corresponding hot plate 1702₁₋₅/cold plate 1704₁₋₅ may be at least partially hollow based on pipes/tubes formed therein. FIG. 18 shows an example first set of tubes 1802_{1-R} formed into the corresponding hot plate 1702₁₋₅/cold plate 1704₁₋₅. Here, each tube 1802_{1-R} may be a hollow pattern formed inside a thickness of the corresponding hot plate 1702₁₋₅/cold plate 1704₁₋₅. In one scenario, a hot input 1760₁₋₅ (or, a cold input 1770₁₋₅) may fill the tubes 1802_{1-R} and flow therethrough; the aforementioned flow may be laminar due to a uniformly parallel first set of tubes 1802_{1-R}.

FIG. 18 also shows an example second set of tubes 1804_{1-S} formed inside the thickness of the corresponding hot plate 1702₁₋₅/cold plate 1704₁₋₅. One or more tubes 1804_{1-S} of second set of tubes 1804_{1-S} may have twists and turns therein that lend quasi-turbulence to a flow of a hot input 1760₁₋₅ (or even a cold input 1770₁₋₅) therethrough. It should be noted that a single convoluted path for a hot input 1760₁₋₅ (or even a cold input 1770₁₋₅) based on twists and turns of a single tube 1804_{1-S} inside the thickness of the corresponding hot plate 1702₁₋₅/cold plate 1704₁₋₅ may also be within the scope of the exemplary embodiments discussed herein. The aforementioned single convoluted path may also provide for quasi-turbulence to the flow of the hot input 1760₁₋₅ (or even the cold input 1770₁₋₅) through the single tube 1804_{1-S}.

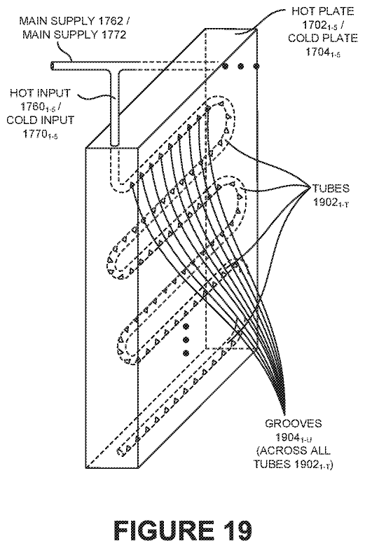

FIG. 19 an example third set of tubes 1902_{1-T} formed inside a thickness of a corresponding hot plate 1702₁₋₅/cold plate 1704₁₋₅. Here, grooves 1904_{1-U} may be formed on a path of each tube 1902_{1-T} to provide for turbulent flow of a hot input 1760₁₋₅/cold input 1770₁₋₅ therethrough. In one or more embodiments, the turbulence generated by grooves 1904_{1-U} may lead to mixing of hot input 1760₁₋₅ (or even cold input 1770₁₋₅) inside the corresponding hot plate 1702₁₋₅ (or cold plate 1704₁₋₅), leading to enhanced heating and, thereby, better heat exchange between the corresponding hot plate 1702₁₋₅/cold plate 1704₁₋₅ and a thin-film based thermoelectric module 1750₁₋₉ in contact therewith. While FIG. 19 shows grooves 1904_{1-U} within each tube 1902_{1-T} as being the same, it should be noted that grooves may vary across tubes 1902_{1-T}.

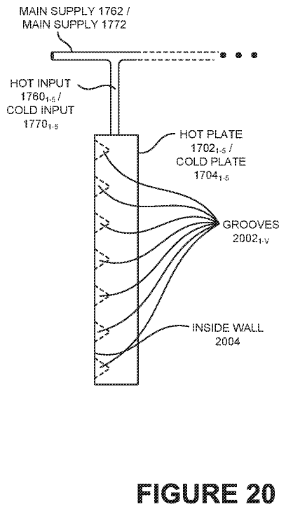

FIG. 20 shows a set of grooves 2002_{1-V} formed within a thickness of a hot plate 1702₁₋₅/cold plate 1704₁₋₅ on an inside wall 2004 thereof. Here, grooves 2002_{1-V} may be corrugations that provide for turbulent flow of hot input 1760₁₋₅ (or even cold input 1770₁₋₅) inside the hot plate 1702₁₋₅/cold plate 1704₁₋₅. The aforementioned corrugations may protrude from inside wall 2004 in a lateral direction to the surface of hot plate 1702₁₋₅/cold plate 1704₁₋₅. All other design configurations (e.g., of grooves, of tubes and/or pipes) for generating turbulent flows (or, even laminar flows) of one or more hot inputs 1760₁₋₅ and/or one or more cold inputs 1760₁₋₅ are within the scope of the exemplary embodiments discussed herein. It should be noted that in FIG. 20, the hot plate 1702₁₋₅/cold plate 1704₁₋₅ may be at least partially hollow to enable grooves 2002_{1-V} to be formed on inside wall 2004. Hot input 1760₁₋₅/cold input 1770₁₋₅ may be obstructed by said grooves 2002_{1-V} to provide for the aforementioned turbulence.

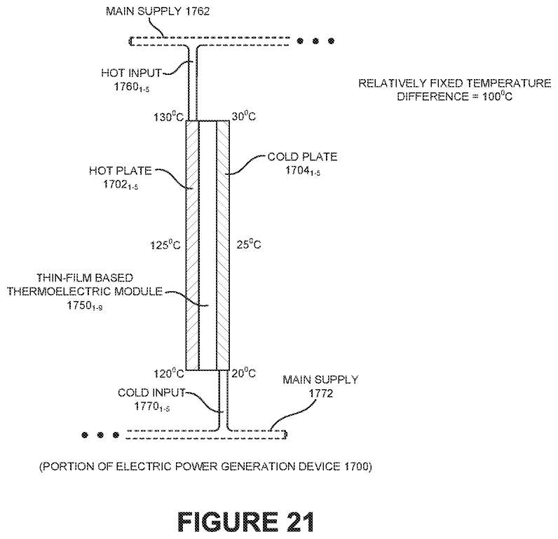

In one or more embodiments, when a thin-film based thermoelectric module 1750₁₋₉ contacts a hot plate 1702₁₋₅ and a cold plate 1704₁₋₅ on either side thereof, the corresponding hot input 1760₁₋₅ within hot plate 1702₁₋₅ may cool down as cold input 1770₁₋₅ within cold plate 1704₁₋₅ is heated up. Thus, in one or more embodiments, a relatively fixed temperature difference may be sustained across the surfaces of hot plate 1702₁₋₅ and cold plate 1704₁₋₅ in contact with thin-film based thermoelectric module 1750₁₋₉. FIG. 21 shows the aforementioned relatively fixed temperature difference (e.g., 100° C.) across the surfaces of hot plate 1702₁₋₅ and cold plate 1704₁₋₅ in contact with thin-film based thermoelectric module 1750₁₋₉.

It should be noted that while FIG. 17 shows a finite number of hot plates 1702₁₋₅, cold plates 1704₁₋₅ and thin-film based thermoelectric modules 1750₁₋₉, concepts discussed herein are extensible across any number of the aforementioned elements. Additionally, it should be noted that substrates may be different across thin-film based thermoelectric modules 1750₁₋₉. Also, it should be noted that, in the case of elastomer encapsulated versions of thin-film based thermoelectric modules 1750₁₋₉, the aforementioned thin-film based thermoelectric modules 1750₁₋₉ may directly contact hot plates 1702₁₋₅ and cold plates 1704₁₋₅ without a need to anodize and/or paint hot plates 1702₁₋₅ and cold plates 1704₁₋₅. In non-elastomer encapsulated versions of thin-film based thermoelectric modules 1750₁₋₉, anodizing and/or painting (e.g., black painting) hot plates 1702₁₋₅ and cold plates 1704₁₋₅ may be required.

In one or more embodiments, thin-film based thermoelectric modules 1750₁₋₉, when placed between hot plates 1702₁₋₅ and cold plates 1704₁₋₅, may produce electric power proportional to a square of a temperature difference between “hot” ends and “cold” ends thereof. In one or more embodiments, while it is preferable to introduce turbulence within hot plates 1702₁₋₅, a target output power may warrant introduction of turbulence also within cold plates 1704₁₋₅, as discussed above. In one or more embodiments, conversion of abundant waste heat into electricity may be accomplished through electric power generation device 1700 without any moving part therefor. Solutions facilitated by exemplary embodiments discussed herein may provide for clean conversion of waste heat into electricity, with no CO₂, NOₓ, SOₓ and no particulate emissions. As the process of manufacturing thin-film based thermoelectric modules 1750₁₋₉ may be scalable (e.g., an area of substrate 350 on which thermoelectric legs are deposited to form a thin-film based thermoelectric module 1750₁₋₉ may even be in the range of m²) and roll-to-roll with advantageous dimensionality, exemplary embodiments discussed herein may be applicable across a diverse set of applications including utility power generation and Internet of Things (IoT) based/smart products. All reasonable variations are within the scope of the exemplary embodiments discussed herein.

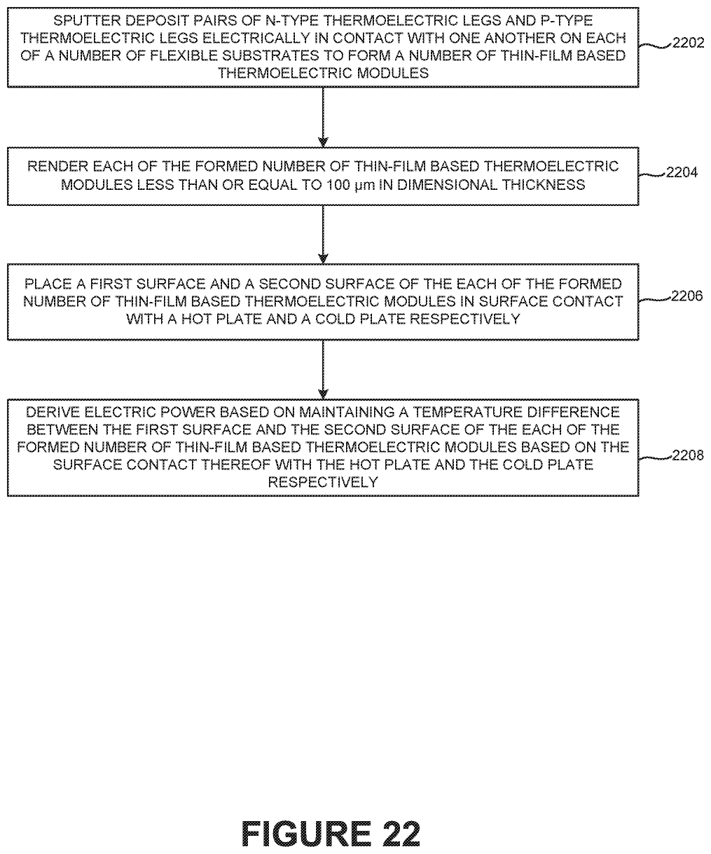

FIG. 22 shows a process flow diagram detailing the operations involved in realizing an electric power generation device (e.g., electric power generation device 1700), according to one or more embodiments. In one or more embodiments, operation 2202 may involve sputter depositing pairs of N-type thermoelectric legs and P-type thermoelectric legs (e.g., the thermoelectric legs of the embodiments of FIGS. 3-9 and FIGS. 13-16) electrically in contact with one another on each of a number of flexible substrates (e.g., flexible substrate 350) to form a number of thin-film based thermoelectric modules (e.g., thin-film based thermoelectric modules 1750₁₋₉). In one or more embodiments, the each of the number of flexible substrates may be Al foil, a sheet of paper, polytetrafluoroethylene, polyimide, plastic, a single-sided Cu clad laminate sheet and/or a double-sided Cu clad laminate sheet, and the each of the number of flexible substrates may have a dimensional thickness less than or equal to 25 μm.

In one or more embodiments, operation 2204 may involve rendering each of the formed number of thin-film based thermoelectric modules less than or equal to 100 μm in dimensional thickness. In one or more embodiments, a layer of the each of the formed number of thin-film based thermoelectric modules including the sputter deposited N-type thermoelectric legs and the P-type thermoelectric legs may have a dimensional thickness less than or equal to 25 μm. In one or more embodiments, operation 2206 may involve placing a first surface (e.g., surface 1752_{1,3,5,7,9}) and a second surface (e.g., 1754_{1,3,5,7,9}) of the each of the formed number of thin-film based thermoelectric modules in surface contact with a hot plate (e.g., hot plate 1702₁₋₅) and a cold plate (e.g., 1704₁₋₅) respectively.

In one or more embodiments, the hot plate and the cold plate may be parallel to one another. In one or more embodiments, the hot plate may be configured to be at a higher temperature than the cold plate. In one or more embodiments, the placing of the each of the formed number of thin-film based thermoelectric modules in surface contact with the hot plate and the cold plate may form the electric power generation device including a number of alternating hot plates and cold plates in between each of which is a thin-film based thermoelectric module of the formed number of thin-film based thermoelectric modules. In one or more embodiments, operation 2208 may then involve deriving electric power from the electric power generation device based on maintaining a temperature difference between the first surface and the second surface of the each of the formed number of thin-film based thermoelectric modules based on the surface contact thereof with the hot plate and the cold plate respectively.

Although the present embodiments have been described with reference to specific example embodiments, it will be evident that various modifications and changes may be made to these embodiments without departing from the broader spirit and scope of the various embodiments. Accordingly, the specification and drawings are to be regarded in an illustrative rather than a restrictive sense.

What is claimed is:

1. A method comprising:
sputter depositing pairs of N-type thermoelectric legs and P-type thermoelectric legs electrically in contact with one another on each of a plurality of flexible substrates to form a plurality of thin-film based thermoelectric modules, the each of the plurality of flexible substrates being at least one of: aluminum (Al) foil, a sheet of paper, polytetrafluoroethylene, polyimide, plastic, a single-sided copper (Cu) clad laminate sheet, and a double-sided Cu clad laminate sheet, and the each of the plurality of flexible substrates having a dimensional thickness less than or equal to 25 μm;
rendering each of the formed plurality of thin-film based thermoelectric modules less than or equal to 100 μm in dimensional thickness, a layer of the each of the formed plurality of thin-film based thermoelectric modules including the sputter deposited N-type thermoelectric legs and the P-type thermoelectric legs having a dimensional thickness less than or equal to 25 μm;
placing a first surface and a second surface of the each of the formed plurality of thin-film based thermoelectric modules in surface contact with a hot plate and a cold plate respectively, the hot plate and the cold plate being parallel to one another, the hot plate configured to be at a higher temperature than the cold plate, and the placing of the each of the formed plurality of thin-film based thermoelectric modules in surface contact with the hot plate and the cold plate forming an electric power generation device comprising a plurality of alternating hot plates and cold plates in between each of which is a thin-film based thermoelectric module of the formed plurality of thin-film based thermoelectric modules; and
deriving electric power from the electric power generation device based on maintaining a temperature difference between the first surface and the second surface of the each of the formed plurality of thin-film based thermoelectric modules based on the surface contact thereof with the hot plate and the cold plate respectively.

2. The method of claim 1, comprising at least one of:
providing a supply of a first fluid and a second fluid to the hot plate and the cold plate respectively to enable the hot plate to be at the higher temperature than the cold plate; and
designing at least one of: the hot plate and the cold plate for one of: a laminar flow and a turbulent flow of a corresponding at least one of: the first fluid and the second fluid therethrough.

3. The method of claim 1, further comprising encapsulating the each of the formed plurality of thin-film based thermoelectric modules with an elastomer, the elastomer providing an encapsulation having a dimensional thickness less than or equal to 15 μm.

4. The method of claim 1, further comprising:
printing and etching a design pattern of metal onto the each of the plurality of flexible substrates to form electrically conductive pads, leads and terminals thereon, the formed electrically conductive pads, the leads and the terminals having a dimensional thickness less than or equal to 18 μm;
additionally electrodepositing a seed metal layer comprising at least one of: Chromium (Cr), Nickel (Ni) and Gold (Au) directly on top of the formed electrically conductive pads, the leads and the terminals on the each of the plurality of flexible substrates following the printing and etching thereof, the seed metal layer having a dimensional thickness less than or equal to 5 μm; and
sputter depositing the pairs of the N-type thermoelectric legs and the P-type thermoelectric legs directly on top of the electrodeposited seed metal layer.

5. The method of claim 1, comprising at least one of: the hot plate and the cold plate being made of one of: steel, a ceramic material and anodized aluminum.

6. The method of claim 1, comprising at least one of:
at least one of: the first fluid and the second fluid being one of: water, steam, a liquid and waste flue gas from at least one of: a furnace, a boiler and a power plant; and
at least one of: the hot plate and the cold plate being painted.

7. The method of claim 2, further comprising designing the at least one of: the hot plate and the cold plate with a plurality of grooves therewithin to enable the turbulent flow of the corresponding at least one of: the first fluid and the second fluid therethrough.

8. A method comprising:
sputter depositing pairs of N-type thermoelectric legs and P-type thermoelectric legs electrically in contact with one another on each of a plurality of flexible substrates to form a plurality of thin-film based thermoelectric modules, the each of the plurality of flexible substrates being at least one of: Al foil, a sheet of paper, polytetrafluoroethylene, polyimide, plastic, a single-sided Cu clad laminate sheet, and a double-sided Cu clad laminate sheet, and the each of the plurality of flexible substrates having a dimensional thickness less than or equal to 25 μm;
rendering each of the formed plurality of thin-film based thermoelectric modules less than or equal to 100 μm in dimensional thickness, a layer of the each of the formed plurality of thin-film based thermoelectric modules including the sputter deposited N-type thermoelectric legs and the P-type thermoelectric legs having a dimensional thickness less than or equal to 25 μm;
placing a first surface and a second surface of the each of the formed plurality of thin-film based thermoelectric modules in surface contact with a hot plate and a cold plate respectively, the hot plate and the cold plate being parallel to one another, and the placing of the each of the formed plurality of thin-film based thermoelectric modules in surface contact with the hot plate and the cold plate forming an electric power generation device comprising a plurality of alternating hot plates and cold plates in between each of which is a thin-film based thermoelectric module of the formed plurality of thin-film based thermoelectric modules;
providing a supply of a first fluid and a second fluid to the hot plate and the cold plate respectively to enable the hot plate to be at a higher temperature than the cold plate; and
deriving electric power from the electric power generation device based on maintaining a temperature difference between the first surface and the second surface of the each of the formed plurality of thin-film based thermoelectric modules based on the surface contact thereof with the hot plate and the cold plate respectively.

9. The method of claim 8, comprising designing at least one of: the hot plate and the cold plate for one of: a laminar flow and a turbulent flow of a corresponding at least one of: the first fluid and the second fluid therethrough.

10. The method of claim 8, further comprising encapsulating the each of the formed plurality of thin-film based thermoelectric modules with an elastomer, the elastomer providing an encapsulation having a dimensional thickness less than or equal to 15 μm.

11. The method of claim 8, further comprising:
printing and etching a design pattern of metal onto the each of the plurality of flexible substrates to form electrically conductive pads, leads and terminals thereon, the formed electrically conductive pads, the leads and the terminals having a dimensional thickness less than or equal to 18 μm;
additionally electrodepositing a seed metal layer comprising at least one of: Cr, Ni and Au directly on top of the formed electrically conductive pads, the leads and the terminals on the each of the plurality of flexible substrates following the printing and etching thereof, the seed metal layer having a dimensional thickness less than or equal to 5 μm; and
sputter depositing the pairs of the N-type thermoelectric legs and the P-type thermoelectric legs directly on top of the electrodeposited seed metal layer.

12. The method of claim 8, comprising at least one of: the hot plate and the cold plate being made of one of: steel, a ceramic material and anodized aluminum.

13. The method of claim 8, comprising at least one of:
at least one of: the first fluid and the second fluid being one of: water, steam, a liquid and waste flue gas from at least one of: a furnace, a boiler and a power plant; and
at least one of: the hot plate and the cold plate being painted.

14. The method of claim 9, further comprising designing the at least one of: the hot plate and the cold plate with a plurality of grooves therewithin to enable the turbulent flow of the corresponding at least one of: the first fluid and the second fluid therethrough.

15. A method comprising:
sputter depositing pairs of N-type thermoelectric legs and P-type thermoelectric legs electrically in contact with one another on each of a plurality of flexible substrates to form a plurality of thin-film based thermoelectric modules, the each of the plurality of flexible substrates being at least one of: Al foil, a sheet of paper, polytetrafluoroethylene, polyimide, plastic, a single-sided Cu clad laminate sheet, and a double-sided Cu clad laminate sheet, and the each of the plurality of flexible substrates having a dimensional thickness less than or equal to 25 μm;
rendering each of the formed plurality of thin-film based thermoelectric modules less than or equal to 100 μm in dimensional thickness, a layer of the each of the formed plurality of thin-film based thermoelectric modules including the sputter deposited N-type thermoelectric legs and the P-type thermoelectric legs having a dimensional thickness less than or equal to 25 μm;
placing a first surface and a second surface of the each of the formed plurality of thin-film based thermoelectric modules in surface contact with a hot plate and a cold plate respectively, the hot plate and the cold plate being parallel to one another, and the placing of the each of the formed plurality of thin-film based thermoelectric modules in surface contact with the hot plate and the cold plate forming an electric power generation device comprising a plurality of alternating hot plates and cold plates in between each of which is a thin-film based thermoelectric module of the formed plurality of thin-film based thermoelectric modules;
providing a supply of a first fluid and a second fluid to the hot plate and the cold plate respectively to enable the hot plate to be at a higher temperature than the cold plate;
designing at least one of: the hot plate and the cold plate for one of: a laminar flow and a turbulent flow of a corresponding at least one of: the first fluid and the second fluid therethrough; and
deriving electric power from the electric power generation device based on maintaining a temperature difference between the first surface and the second surface of the each of the formed plurality of thin-film based thermoelectric modules based on the surface contact thereof with the hot plate and the cold plate respectively.

16. The method of claim 15, further comprising encapsulating the each of the formed plurality of thin-film based thermoelectric modules with an elastomer, the elastomer providing an encapsulation having a dimensional thickness less than or equal to 15 μm.

17. The method of claim 15, further comprising:
printing and etching a design pattern of metal onto the each of the plurality of flexible substrates to form electrically conductive pads, leads and terminals thereon, the formed electrically conductive pads, the leads and the terminals having a dimensional thickness less than or equal to 18 μm;
additionally electrodepositing a seed metal layer comprising at least one of: Cr, Ni and Au directly on top of the formed electrically conductive pads, the leads and the terminals on the each of the plurality of flexible substrates following the printing and etching thereof, the seed metal layer having a dimensional thickness less than or equal to 5 μm; and
sputter depositing the pairs of the N-type thermoelectric legs and the P-type thermoelectric legs directly on top of the electrodeposited seed metal layer.

18. The method of claim 15, comprising at least one of: the hot plate and the cold plate being made of one of: steel, a ceramic material and anodized aluminum.

19. The method of claim 15, comprising at least one of:
at least one of: the first fluid and the second fluid being one of: water, steam, a liquid and waste flue gas from at least one of: a furnace, a boiler and a power plant; and
at least one of: the hot plate and the cold plate being painted.

20. The method of claim 15, further comprising designing the at least one of: the hot plate and the cold plate with a plurality of grooves therewithin to enable the turbulent flow of the corresponding at least one of: the first fluid and the second fluid therethrough.
